(19) United States
(12) Patent Application Publication
(10) Pub. No.: US 2026/0173925 A1
(43) Pub. Date: Jun. 18, 2026

(54) SEMICONDUCTOR PACKAGES AND METHODS OF FORMING THE SAME

(71) Applicant: Taiwan Semiconductor Manufacturing Co., Ltd., Hsinchu (TW)

(72) Inventors: Po-Ching Wu, Hsinchu (TW); Meng-Tsan Lee, Hsinchu (TW); Li-Han Hsu, Hsinchu (TW); An-Jhih Su, Taoyuan (TW)

(21) Appl. No.: 19/093,508

(22) Filed: Mar. 28, 2025

Related U.S. Application Data
(60) Provisional application No. 63/735,658, filed on Dec. 18, 2024.

(51) Int. Cl. H10W 70/65; H10W 40/60; H10W 74/01; H10W 74/10; H10W 90/00

(52) U.S. Cl. CPC H10W 70/65; H10W 40/611; H10W 74/014; H10W 74/016; H10W 74/121; H10W 90/701

(57) ABSTRACT

A device includes a substrate package comprising component substrates and a first encapsulant around and between the component substrates. A wafer package is attached to a first side of the substrate package and includes integrated circuit devices and a second encapsulant around and between the integrated circuit devices. Voltage regulators are attached to a second side of the substrate package, with the component substrates electrically connecting the voltage regulators to the integrated circuit devices. External connectors are also attached to the second side of the substrate package, with the component substrates electrically connecting the external connectors to the integrated circuit devices.

### PRIORITY CLAIM AND CROSS-REFERENCE

This application claims the benefit of U.S. Provisional Application No. 63/735,658, filed on December 18, 2024, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2A-2B are cross-sectional views of die stacks.

FIGS. 3-8 are cross-sectional views of intermediate stages in the manufacturing of a wafer package, in accordance with some embodiments.

FIG. 9 is a cross-sectional view of a wafer package, in accordance with some embodiments.

FIGS. 10-19 are cross-sectional views of intermediate stages in the manufacturing of a component substrate, in accordance with some embodiments.

FIGS. 20-25 are views of intermediate stages in the manufacturing of a substrate package, in accordance with some embodiments.

FIG. 26 is a cross-sectional view of a system-on-wafer assembly, in accordance with some embodiments.

FIGS. 27-28 are views of intermediate stages in the manufacturing of a substrate package, in accordance with some embodiments.

FIG. 29 is a cross-sectional view of a system-on-wafer assembly, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a system package includes a wafer package attached to a substrate package. The substrate package includes multiple component substrates encapsulated in a first encapsulant, while the wafer package includes multiple integrated circuit devices encapsulated in a second encapsulant. The wafer package is attached to a first side of the substrate package. Voltage regulators and external connectors are attached to a second side of the substrate package, with the component substrates electrically connecting these components to the integrated circuit devices.

The substrate package may incorporate separate component substrates for power distribution and external connection. The component substrates can be individually tested and verified as known good substrates before integration into the substrate package, potentially improving overall yield and reliability. Furthermore, different types of component substrates may be used within the same package; for example, some component substrates may include passive devices while others may be coreless, allowing for customization based on specific power, signal, or space requirements of different regions within the system package.

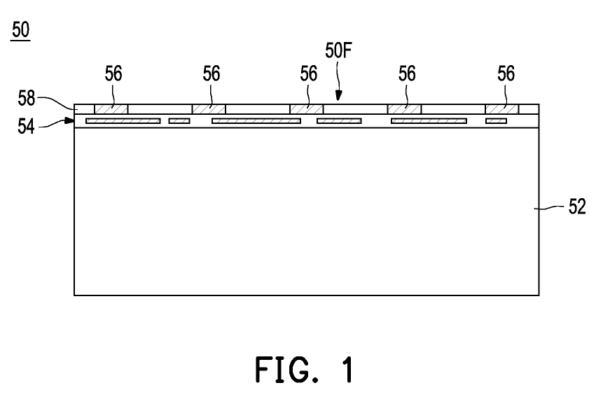

FIG. 1 is a cross-sectional view of an integrated circuit die 50. Multiple integrated circuit dies 50 will be packaged in subsequent processing. Each integrated circuit die 50 may be a logic die (e.g., central processing unit (CPU), graphics processing unit (GPU), system-on-a-chip (SoC) die, microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) are at the active surface of the semiconductor substrate 52. The devices may be active devices (e.g., transistors, diodes, etc.), capacitors, resistors, etc. The inactive surface may be free of devices.

The interconnect structure 54 is over the active surface of the semiconductor substrate 52, and is used to electrically connect the devices of the semiconductor substrate 52 together to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide, nitrides such as silicon nitride, combinations thereof such as silicon oxynitride, or the like. Other dielectric materials may also be used, such as polymers, such as polybenzoxazole (PBO), polyimide, a benzocyclobuten (BCB) based polymer, or the like. The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Die connectors 56 are at the front-side 50F of the integrated circuit die 50. The die connectors 56 may be conductive pillars, pads, or the like, to which external connections are made. The die connectors 56 may be in and/or on the interconnect structure 54. For example, the die connectors 56 may be part of an upper metallization layer of the interconnect structure 54. The die connectors 56 may be formed of a metal, such as copper, aluminum, or the like, and may be formed by, for example, plating, or the like.

Optionally, solder regions (not separately illustrated) may be disposed on the die connectors 56 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 56. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed.

A dielectric layer 58 is at the front-side 50F of the integrated circuit die 50. The dielectric layer 58 may be in and/or on the interconnect structure 54. For example, the dielectric layer 58 may be an upper dielectric layer of the interconnect structure 54. The dielectric layer 58 may be an oxide, a nitride, a polymer, the like, or a combination thereof, which may be formed, for example, by spin coating, lamination, chemical vapor deposition (CVD), or the like. The dielectric layer 58 may laterally encapsulate the die connectors 56. Front-side surfaces of the die connectors 56 and the dielectric layer 58 may be substantially coplanar (within process variations) at the front-side 50F of the integrated circuit die 50.

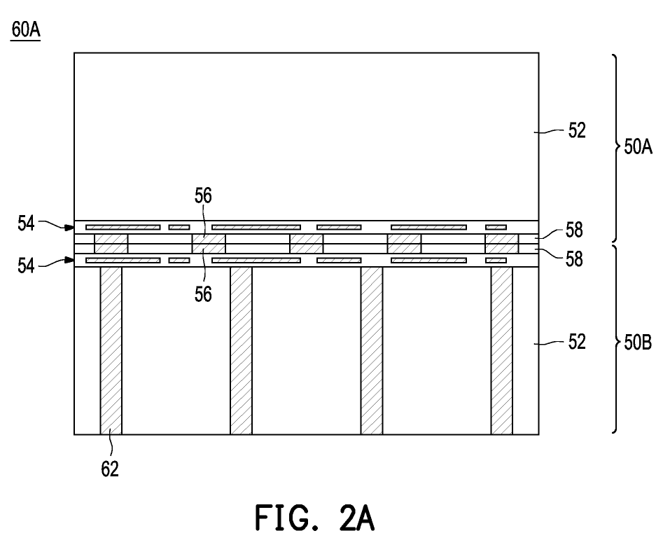

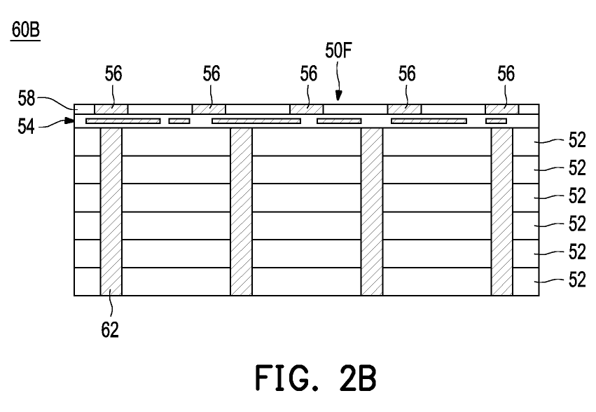

FIGS. 2A-2B are cross-sectional views of die stacks 60A, 60B, respectively. The die stacks 60A, 60B may each have a single function (e.g., a logic device, memory die, etc.), or may each have multiple functions. In some embodiments, the die stack 60A is a logic device such as a system-on-integrated-chip (SoIC) device and the die stack 60B is a memory device such as high bandwidth memory (HBM) device.

As shown in FIG. 2A, the die stack 60A includes two bonded integrated circuit dies 50 (e.g., a first integrated circuit die 50A and a second integrated circuit die 50B). In some embodiments, the first integrated circuit die 50A is a logic die and the second integrated circuit die 50B is an interface die. An interface die bridges a logic die to memory dies, and translates commands between the logic die and the memory dies. In some embodiments, the first integrated circuit die 50A and the second integrated circuit die 50B are bonded such that the active surfaces are facing each other (e.g., are “face-to-face” bonded). Conductive vias 62 may be formed through one of the integrated circuit dies 50 so that external connections may be made to the die stack 60A. The conductive vias 62 may be through-substrate vias (TSVs), such as through-silicon vias or the like. In the illustrated embodiment, the conductive vias 62 are formed in the second integrated circuit die 50B (e.g., the interface die). The conductive vias 62 extend through the semiconductor substrate 52 of the respective integrated circuit die 50, to be physically and electrically connected to the metallization layer(s) of the interconnect structure 54.

As shown in FIG. 2B, the die stack 60B is a stacked device that includes multiple semiconductor substrates 52. For example, the die stack 60B may be a stacked memory device that includes multiple memory dies such as a hybrid memory cube (HMC) device, a high bandwidth memory (HBM) cube, or the like. Each semiconductor substrate 52 may (or may not) have a separate interconnect structure 54. The semiconductor substrates 52 are connected by conductive vias 62, such as TSVs.

As subsequently described, a system package will be formed by packaging integrated circuit devices. The integrated circuit devices may be integrated circuit dies (similar to the integrated circuit die 50 described for FIG. 1) or may be die stacks (similar to the die stacks 60A, 60B described for FIGS. 2A-2B). The system package has multiple computing sites and multiple connecting sites. Each integrated circuit device in the system package may have e.g., logic functions, memory functions, or the like, and the system package may be a single computing system including the computing sites and connecting sites, such as a system-on-wafer (SoW). For example, the system package may be an artificial intelligence (AI) accelerator, and each computing site may be a neural network node for the AI accelerator. The connecting sites may include external connectors for connecting the computing sites to an external system. Example external systems that may implement the system package include AI servers, high-performance computing (HPC) systems, high power computing devices, cloud computing systems, edge computing systems, and the like.

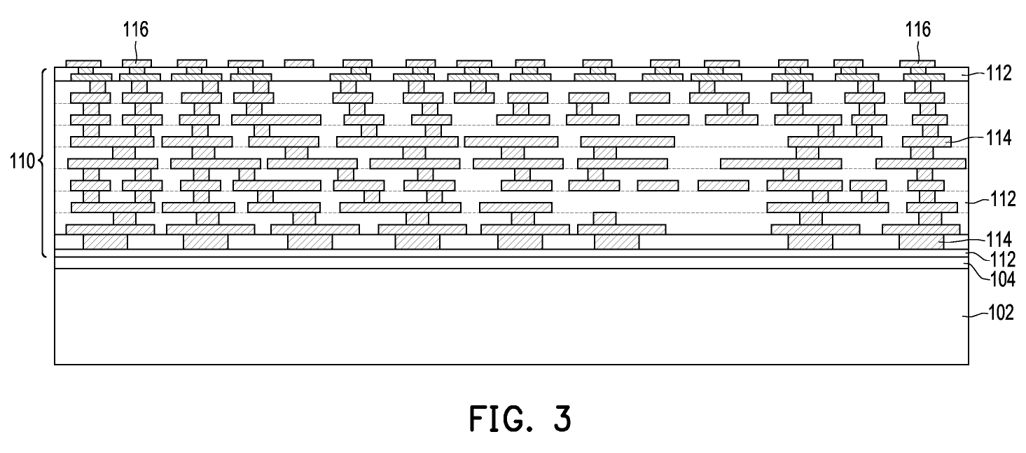

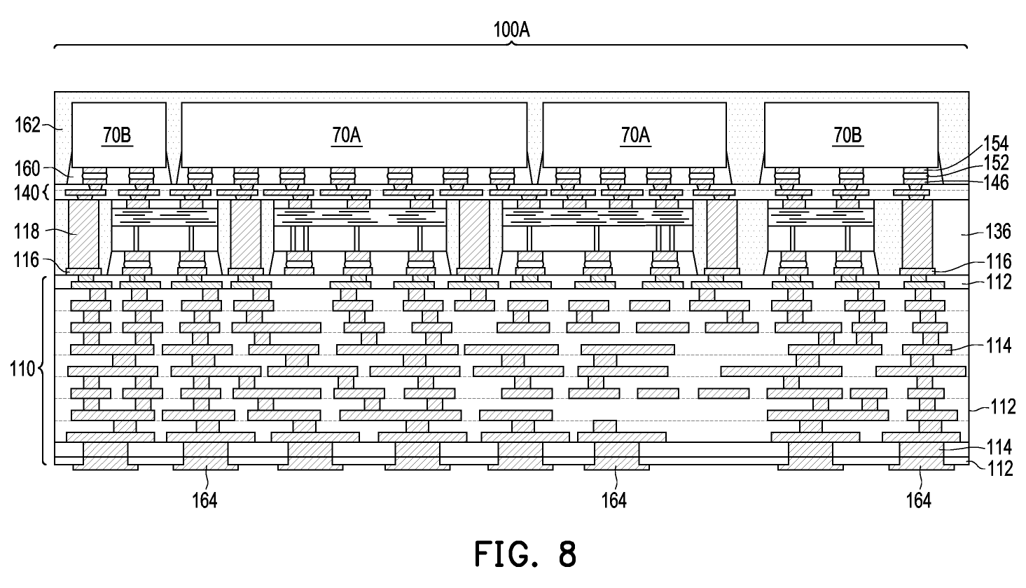

FIGS. 3-8 are cross-sectional views of intermediate stages in the manufacturing of a wafer package 100A (see FIG. 8), in accordance with some embodiments. The wafer package 100A is a reconstituted wafer including integrated circuit devices in an encapsulant. The wafer package 100A will be subsequently attached to a substrate package to form a system package.

In FIG. 3, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer.

The release layer 104 may be formed of a polymer-based material, which may be removed along with the carrier substrate 102 from the overlying structure that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV light. The release layer 104 may be dispensed as a liquid and cured, may be a laminate film laminated onto the carrier substrate 102, or may be the like. The upper surface of the release layer 104 may be leveled and may have a high degree of planarity.

A back-side redistribution structure 110 is formed on the release layer 104. The back-side redistribution structure 110 includes dielectric layers 112 and metallization layers 114 (sometimes referred to as redistribution layers or redistribution lines) among the dielectric layers 112. Thus, the back-side redistribution structure 110 includes metallization layers 114 separated from each other by respective dielectric layers 112.

The dielectric layers 112 may each be formed of a suitable dielectric material. In some embodiments, the dielectric layers 112 are formed of silicon oxide, silicon nitride, silicon oxynitride, or the like, which may be formed by a suitable deposition process such as CVD, ALD, or the like. In some embodiments, the dielectric layers 112 are formed of a polymer, which may be a photosensitive material such as PBO, polyimide, a BCB-based polymer, or the like, that may be patterned using a lithography mask, which may be formed by spin coating, lamination, CVD, or the like. In some embodiments, the dielectric layers 112 are formed of a molding compound, which may include a resin having fillers disposed therein. Examples of resins include epoxy, acrylic, or polyimide-based materials. Examples of fillers include silica or the like. The molding compound may be applied by compression molding, transfer molding, or the like, and may be applied in liquid or semi-liquid form and then subsequently cured.

The metallization layers 114 each include conductive vias and/or conductive lines. The conductive vias extend through respective dielectric layers 112, and the conductive lines extend along respective dielectric layers 112. The metallization layers 114 may be formed of a conductive material. The conductive material may include a metal or a metal alloy, such as copper, titanium, tungsten, aluminum, the like, or combinations thereof. The metallization layers 114 may be composite layers including a plurality of sub-layers formed of different materials.

As an example to form a layer of the back-side redistribution structure 110, a dielectric layer 112 may be formed of a polymer. After the dielectric layer 112 is formed, it may be patterned to expose underlying conductive features (if present), such as an underlying metallization layer. The patterning may be by any acceptable process, such as by exposing the dielectrics layers to light when the dielectric layers 112 are a photosensitive material, or by etching using, for example, an anisotropic etch. If the dielectric layers 112 are photosensitive materials, the dielectric layers 112 can be developed after the exposure. A metallization layer 114 is then formed. For example, a seed layer (not separately illustrated) may be formed over the respective underlying features. The seed layer can be formed on the dielectric layer 112 and in any openings through the dielectric layer 112. In some embodiments, the seed layer includes a titanium layer and a copper layer over the titanium layer. The seed layer may be formed using a deposition process, such as physical vapor deposition (PVD) or the like. A photoresist is then formed and patterned on the seed layer. The photoresist may be formed by spin coating or the like and may be exposed to light for patterning. The pattern of the photoresist corresponds to a metallization layer 114. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the metallization layer 114

As another example to form a layer of the back-side redistribution structure 110, a metallization layer 114 may be formed. For example, a seed layer (not separately illustrated) may be formed over the respective underlying features, such as an underlying dielectric layer. In some embodiments, the seed layer includes a titanium layer and a copper layer over the titanium layer. The seed layer may be formed using a deposition process, such as physical vapor deposition (PVD) or the like. A first photoresist is then formed and patterned on the seed layer. The first photoresist may be formed by spin coating or the like and may be exposed to light for patterning. The pattern of the first photoresist corresponds to conductive lines for the metallization layer 114. The patterning forms openings through the first photoresist to expose the seed layer. A conductive material is formed in the openings of the first photoresist and on the exposed portions of the seed layer. The conductive material may be formed by plating, such as electroless plating or electroplating from the seed layer, or the like. Then, the first photoresist is removed. The first photoresist may be removed by an acceptable ashing or stripping process, such as using an oxygen plasma or the like. A second photoresist is then formed and patterned on the seed layer and the conductive lines. The second photoresist may be formed by spin coating or the like and may be exposed to light for patterning. The pattern of the second photoresist corresponds to conductive vias for the metallization layer 114. The patterning forms openings through the second photoresist to expose the conductive lines. Additional conductive material is formed in the openings of the second photoresist and on the exposed portions of the conductive lines. The conductive material may be formed by plating, such as electroless plating or electroplating from the conductive lines, or the like. In some embodiments, no seed layers are formed between the conductive lines and the conductive vias. Then, the second photoresist and portions of the seed layer on which the conductive material are not formed are removed. The second photoresist may be removed by an acceptable ashing or stripping process, such as using an oxygen plasma or the like. After the second photoresist is removed, exposed portions of the seed layer are removed, such as by using an acceptable etching process, such as by wet or dry etching. The remaining portions of the seed layer and conductive material form the metallization layer 114. A dielectric layer 112 is formed around the metallization layer 114. The dielectric layer 112 may be formed of a molding compound. The dielectric layer 112 may be formed over the metallization layer 114 such that the metallization layer 114 is buried or covered. A planarization process may then be performed on the dielectric layer 112 to expose the conductive vias of the metallization layer 114. Upper surfaces of the dielectric layer 112 and metallization layer 114 are substantially coplanar (within process variations) after the planarization process. The planarization process may be, for example, a chemical-mechanical polish (CMP).

The back-side redistribution structure 110 may include a combination of different types of dielectric layers 112. In some embodiments, certain dielectric layers 112 may be formed of polymer (as previously described) while other dielectric layers 112 within the same structure may be formed of molding compound (as previously described). This hybrid approach may allow for tailored properties in different regions of the redistribution structure. For example, polymer-based dielectric layers may be used in areas where precise patterning through lithography is performed, while molding compound layers may be used in regions benefiting from their specific mechanical or electrical properties.

The back-side redistribution structure 110 is illustrated as an example. More or fewer dielectric layers 112 and metallization layers 114 than illustrated may be formed by performing the previously described steps any desired quantity of times.

Under-bump metallization layers (UBMLs) 116 are formed for subsequent connection to the back-side redistribution structure 110. The UBMLs 116 have bump portions on and extending along the major surface of the upper dielectric layer 112 of the back-side redistribution structure 110, and have via portions extending through the upper dielectric layer 112 of the back-side redistribution structure 110 to physically and electrically couple the upper metallization layer 114 of the back-side redistribution structure 110. The UBMLs 116 may be formed of the same material as the metallization layers 114, and may be formed by a similar process as the metallization layers 114. In some embodiments, the UBMLs 116 have a different size than the metallization layers 114.

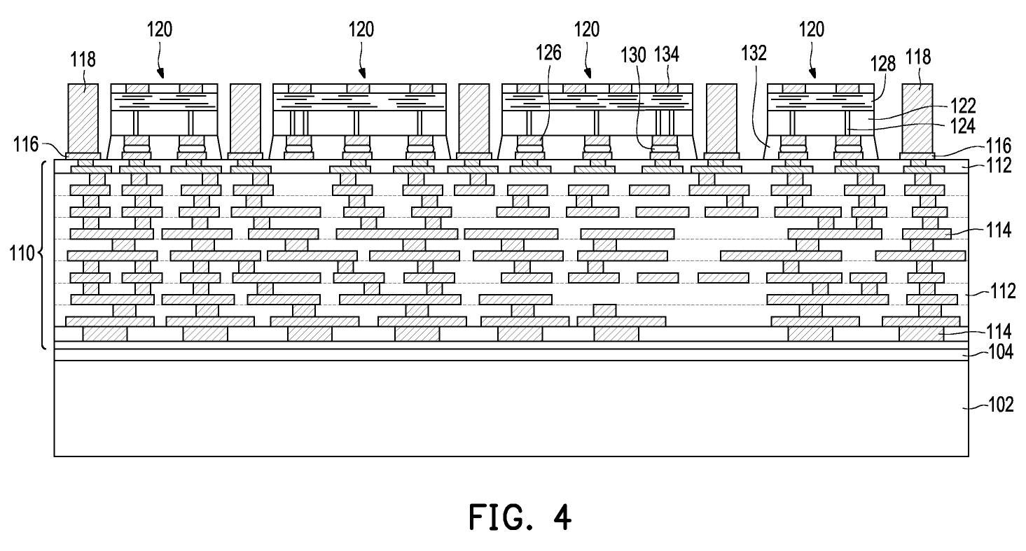

In FIG. 4, through vias 118 are formed on a first subset of the UBMLs 116. Additionally, interconnection dies 120 are attached to a second subset of the UBMLs 116. The second subset of the UBMLs 116 remain free of the through vias 118. The first subset of the UBMLs 116 and the through vias 118 will be subsequently utilized for connection to higher layers of the wafer package. The second subset of the UBMLs 116 and the interconnection dies 120 will be subsequently utilized for direct communication between integrated circuit devices of the resulting wafer package.

As an example to form the through vias 118, a photoresist is formed and patterned on the UBMLs 116 and the back-side redistribution structure 110. The photoresist may be formed by spin coating or the like and may be exposed to light for patterning. The pattern of the photoresist corresponds to the through vias 118. The patterning forms openings through the photoresist to expose the UBMLs 116. A conductive material is formed in the openings of the photoresist and on the exposed portions of the UBMLs 116. The conductive material may be formed by plating, such as electroplating or electroless plating, or the like. The conductive material of the through vias 118 may be directly plated from a conductive material of the UBMLs 116. The conductive material may include a metal, like copper, titanium, tungsten, aluminum, or the like. The photoresist is then removed. The photoresist may be removed by an acceptable ashing or stripping process, such as using an oxygen plasma or the like. The remaining portions of the conductive material form the through vias 118.

Each interconnection die 120 may be a local silicon interconnect (LSI), a large scale integration package, an interposer die, or the like. Each interconnection die 120 includes a substrate 122, with conductive features formed in and/or on the substrate 122. The substrates 122 may include a semiconductor substrate, one or more dielectric layer(s), or the like. Additionally, each interconnection die 120 may include through-substrate vias (TSVs) 124 that extend into or through the substrate 122, and may be coupled to the conductive features of the interconnection die 120. An interconnection die 120 is attached to the UBMLs 116 using die connectors 126 disposed at the back-side of the interconnection die 120. Some of the die connectors 126 may be electrically coupled to the front-side of the interconnection die 120 by the TSVs 124. As subsequently described in greater detail, the TSVs 124 are small, such as smaller than the through vias 118. As a result of the TSVs 124 being small, they may have a greater density, thereby increasing the amount of connections to the interconnection dies 120.

In embodiments where the interconnection dies 120 are LSIs, the interconnection dies 120 may be bridge structures that include die bridges 128. The die bridges 128 may be metallization layers formed in and/or on, e.g., the substrate 122, and work to interconnect overlying integrated circuit devices (subsequently described) to one another. The die bridges 128 are located at the front-side of the interconnection dies 120. As such, the LSIs can be used to directly connect and allow communication between the integrated circuit devices. In such embodiments, the interconnection dies 120 can be placed in regions that are disposed between the subsequently attached integrated circuit devices, so that each interconnection die 120 overlaps multiple overlying integrated circuit devices. In some embodiments, the interconnection dies 120 may further include logic devices and/or memory devices. In some embodiments, the interconnection dies 120 may be free of logic devices and/or memory devices. The interconnection dies 120 are attached to the UBMLs 116 such that the die bridges 128 face away from the back-side redistribution structure 110.

In the illustrated embodiment, the interconnection dies 120 are attached to the back-side redistribution structure 110 (via the UBMLs 116) with solder bonds, such as with conductive connectors 130. The conductive connectors 130 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 130 may include a conductive material such as solder, copper, aluminum, gold, nickel, silver, palladium, tin, the like, or a combination thereof. In some embodiments, the conductive connectors 130 are formed by initially forming a layer of solder through evaporation, electroplating, printing, solder transfer, ball placement, or the like. Once a layer of solder has been formed, a reflow may be performed in order to shape the material into the desired bump shapes. Attaching the interconnection die 120 to the UBMLs 116 may include placing the interconnection die 120 on the UBMLs 116 (e.g., using a pick-and-place process) and reflowing the conductive connectors 130 to physically and electrically couple the die connectors 126 to the UBMLs 116. In another embodiment, the interconnection dies 120 are attached to the back-side redistribution structure 110 with direct bonds, using the die connectors 126.

In some embodiments, an underfill 132 is formed around the conductive connectors 130, and between the back-side redistribution structure 110 and the interconnection dies 120. The underfill 132 may reduce stress and protect the joints resulting from the reflowing of the conductive connectors 130. The underfill 132 may also be used to securely bond the interconnection dies 120 to the back-side redistribution structure 110 and provide structural support and environmental protection. The underfill 132 may be formed of a molding compound, epoxy, or the like. The underfill 132 may be formed by a capillary flow process after the interconnection dies 120 are attached, or may be formed by a suitable deposition method before the interconnection dies 120 are attached. The underfill 132 may be applied in liquid or semi-liquid form and then subsequently cured.

Optionally, the interconnection dies 120 may include die connectors 134 disposed at the front-side of the interconnection die 120. The die connectors 134 may be electrically coupled to the die bridges 128.

The interconnection dies 120 may be optional components in the wafer package. The inclusion or exclusion of interconnection dies 120 may depend on specific design requirements, performance goals, or manufacturing considerations. Additionally, while the interconnection dies 120 may be implemented as local silicon interconnects (LSIs) in some cases, alternative components such as integrated voltage regulators (IVRs) or integrated passive devices (IPDs) may be used in place of LSIs. These alternative components may provide different functionalities or advantages depending on the specific needs of the wafer package. For example, IVRs may offer improved power management capabilities, while IPDs may provide enhanced passive component integration within the wafer package.

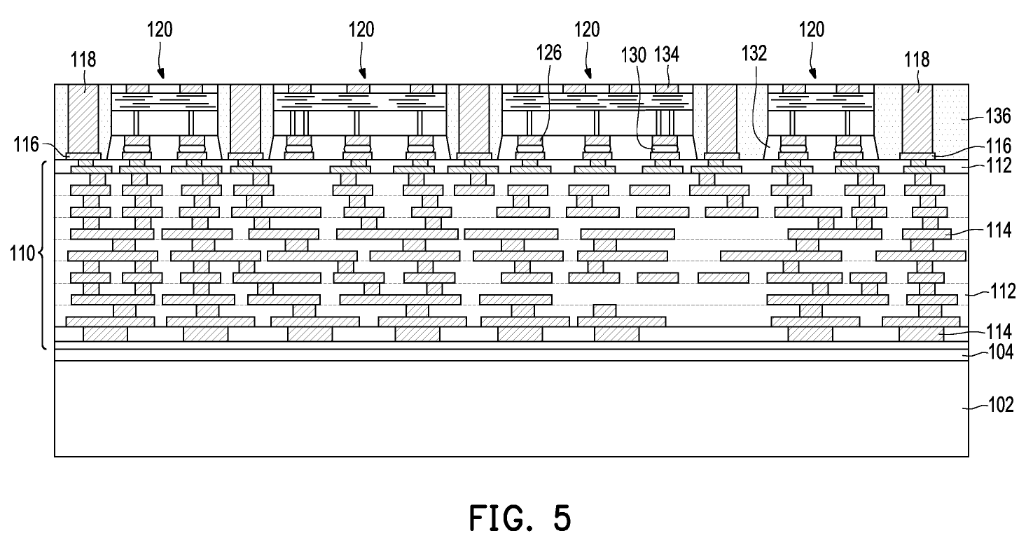

In FIG. 5, an encapsulant 136 is formed on and around the various components. After formation, the encapsulant 136 encapsulates the UBMLs 116, the through vias 118, the interconnection dies 120, and/or the underfill 132. The encapsulant 136 may be a molding compound, epoxy, or the like. The encapsulant 136 may be applied by compression molding, transfer molding, or the like, and may be formed over the carrier substrate 102 such that the through vias 118 and/or the interconnection dies 120 are buried or covered. The encapsulant 136 is further formed in gap regions between the interconnection dies 120 and the through vias 118. The encapsulant 136 may be applied in liquid or semi-liquid form and then subsequently cured.

A planarization process may optionally be performed on the encapsulant 136 to expose the through vias 118 and the interconnection dies 120 (e.g., the die connectors 134). The planarization process may remove material of the through vias 118, the interconnection dies 120, and/or the encapsulant 136 until the interconnection dies 120 and the through vias 118 are exposed. The upper surfaces of the through vias 118, the die connectors 134, and the encapsulant 136 are substantially coplanar (within process variations) after the planarization process. The planarization process may be, for example, a chemical-mechanical polish (CMP), a grinding process, or the like. In some embodiments, the planarization may be omitted, for example, if the through vias 118 and/or the die connectors 134 are already exposed. After the planarization process, the through vias 118 extend through the encapsulant 136. As such, the through vias 118 may be referred to as through-mold vias (TMVs).

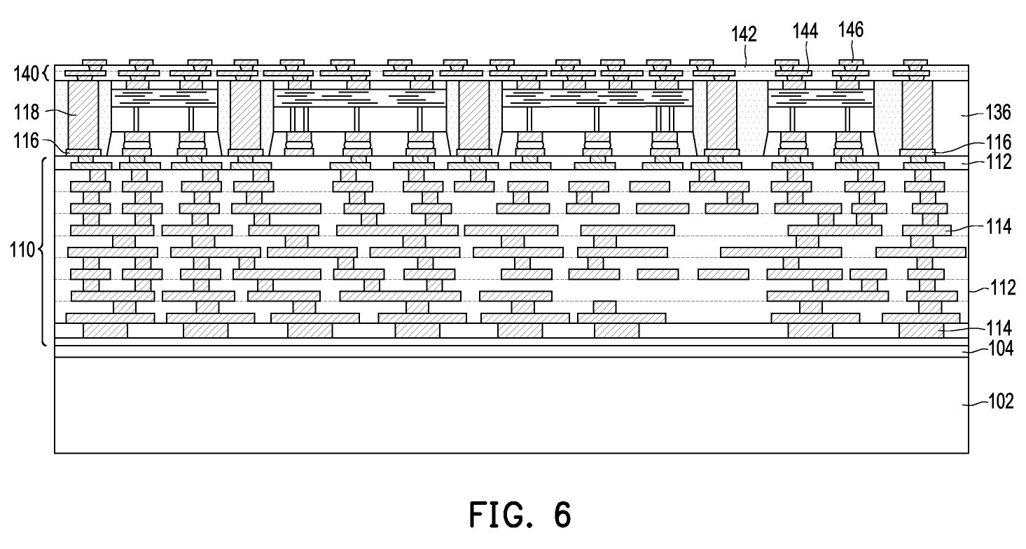

In FIG. 6, a front-side redistribution structure 140 is formed on the front-side surfaces of the encapsulant 136, the interconnection dies 120 (e.g., the die connectors 134), and the through vias 118. The front-side redistribution structure 140 includes dielectric layers 142 and metallization layer(s) 144 (sometimes referred to as redistribution layers or redistribution lines) among the dielectric layers 142. Thus, the front-side redistribution structure 140 includes metallization layer(s) 144 separated from each other by respective dielectric layers 142. The metallization layer(s) 144 of the front-side redistribution structure 140 are connected to the through vias 118 and to the interconnection dies 120 (e.g., the die connectors 134).

In some embodiments, the dielectric layers 142 are formed of a polymer, which may be a photosensitive material such as PBO, polyimide, a BCB-based polymer, or the like, that may be patterned using a lithography mask. In other embodiments, the dielectric layers 142 are formed of a nitride such as silicon nitride, an oxide such as silicon oxide, or the like. The dielectric layers 142 may be formed by spin coating, lamination, CVD, the like, or a combination thereof. After a dielectric layer 142 is formed, it may be patterned to expose underlying conductive features, such as portions of the through vias 118, the die connectors 134, and/or the metallization layer(s) 144. The patterning may be by any acceptable process, such as by exposing the dielectric layers 142 to light when they are formed of photosensitive material, or by etching using, for example, an anisotropic etch. If the dielectric layers 142 are formed of a photosensitive material, the dielectric layers 142 may be developed after the exposure.

The metallization layer(s) 144 each include conductive vias and/or conductive lines. The conductive vias extend through respective dielectric layers 142, and the conductive lines extend along respective dielectric layers 142. As an example to form a metallization layer 144, a seed layer (not separately illustrated) is formed over the respective underlying features. For example, the seed layer may be formed on a respective dielectric layer 142 and in any openings through the respective dielectric layer 142. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 144. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 144 of the front-side redistribution structure 140.

The front-side redistribution structure 140 is illustrated as an example. More or fewer dielectric layers 142 and metallization layer(s) 144 than illustrated may be formed by performing the previously described steps any desired quantity of times.

Other variations of the front-side redistribution structure 140 are contemplated. For example, some of the dielectric layers 142 may be formed of an encapsulant, such as a molding compound, epoxy, or the like. A metallization layer 144 may be formed by plating a conductive via from a conductive line. A dielectric layer 142 may be formed by encapsulating that metallization layer 144. Any desired stack of materials may be used for the dielectric layers 142.

Under-bump metallizations (UBMs) 146 may be formed through the upper dielectric layer 142 of the front-side redistribution structure 140. The UBMs 146 are physically and electrically coupled to the upper metallization layer 144 of the front-side redistribution structure 140. The UBMs 146 each include conductive vias and conductive bumps. The conductive vias extend through the upper dielectric layer 142, and the conductive bumps extend along the upper dielectric layer 142. The UBMs 146 may be formed of the same material(s) as the metallization layer(s) 144. In some embodiments, the UBMs 146 have a different size than the metallization layer(s) 144.

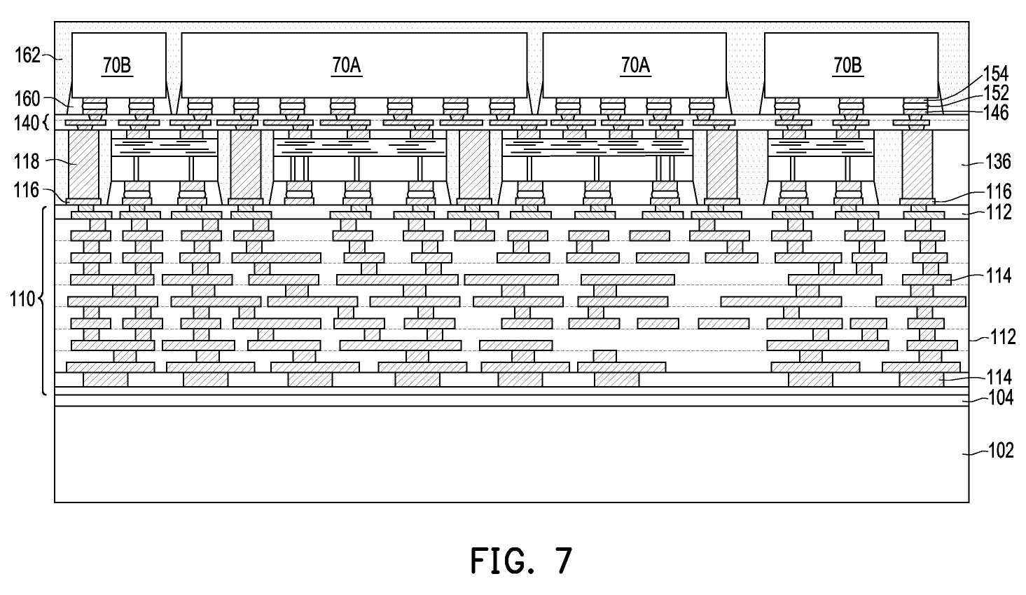

In FIG. 7, integrated circuit devices 70 are attached to the front-side redistribution structure 140. A desired type and quantity of integrated circuit devices 70 are adjacent one another. In some embodiments, the integrated circuit devices 70 include a first type of integrated circuit device (such as computing devices 70A) and a second type of integrated circuit device (such as interface devices 70B). The computing devices 70A and the interface devices 70B may be formed in processes of a same technology node, or may be formed in processes of different technology nodes. For example, the computing devices 70A may be formed by a more advanced process node than the interface devices 70B.

Each computing device 70A may include a logic die, a memory die, and/or the like. The computing devices 70A may be integrated circuit dies (similar to the integrated circuit die 50 described for FIG. 1) or may be die stacks (similar to the die stacks 60A, 60B described for FIGS. 2A-2B). In some embodiments, the computing devices 70A are system-on-a-chip (SoC) dies. In some embodiments, the computing devices 70A are die stacks, such as system-on-integrated-chip (SoIC) devices. Each die stack may include a system-on-a-chip (SoC) die and one or more HBM dies. In some embodiments, the computing device 70A include various combinations of logic components, such as system-on-chip (SoC) dies or I/O dies, along with other specialized components. These combinations may incorporate memory modules, silicon photonic elements, or integrated passive devices (IPDs).

Each interface device 70B may include input/output interfaces, memory controllers, network interfaces, or other types of interface circuitry to bridge communication between the computing devices 70A and external components. The interface devices 70B may translate commands and data between protocols used by the computing devices 70A and protocols used by the external components. The interface devices 70B may be integrated circuit dies (similar to the integrated circuit die 50 described for FIG. 1) or may be die stacks (similar to the die stacks 60A, 60B described for FIGS. 2A-2B). In some embodiments, the interface devices 70B are I/O dies.

The interface devices 70B may be arranged around the computing devices 70A to facilitate connections to external systems. In particular, the interface devices 70B may surround the computing devices 70A in a top-down view (subsequently described). This arrangement may allow for shorter electrical paths between the interface devices 70B and external connectors (subsequently described) that will be attached to the system package.

In the illustrated embodiment, the integrated circuit devices 70 are attached to the front-side redistribution structure 140 with solder bonds, such as with conductive connectors 152. The conductive connectors 152 may be formed of a conductive material that is reflowable, such as solder, copper, aluminum, gold, nickel, silver, palladium, tin, the like, or a combination thereof. In some embodiments, the conductive connectors 152 are formed by initially forming a layer of solder through methods such as evaporation, electroplating, printing, solder transfer, ball placement, or the like. Once a layer of solder has been formed, a reflow may be performed in order to shape the conductive connectors 152 into desired bump shapes. Attaching the integrated circuit devices 70 to the front-side redistribution structure 140 may include placing the integrated circuit devices 70 on the front-side redistribution structure 140 and reflowing the conductive connectors 152. The integrated circuit devices 70 may be placed on the front-side redistribution structure 140 using, e.g., a pick-and-place tool. The conductive connectors 152 are reflowed to attach die connectors 154 at the front-sides of the integrated circuit devices 70 to the UBMs 146 of the front-side redistribution structure 140, thereby electrically connecting the front-side redistribution structure 140 to the integrated circuit devices 70. In another embodiment, the integrated circuit devices 70 are attached to the front-side redistribution structure 140 with direct bonds, using the die connectors 154.

In some embodiments, an underfill 160 is formed around the conductive connectors 152, and between the front-side redistribution structure 140 and the integrated circuit devices 70. The underfill 160 may reduce stress and protect the joints resulting from the reflowing of the conductive connectors 152. The underfill 160 may be formed of an underfill material such as a molding compound, epoxy, or the like. The underfill 160 may be formed by a capillary flow process after the integrated circuit devices 70 are attached to the front-side redistribution structure 140, or may be formed by a suitable deposition method before the integrated circuit devices 70 are attached to the front-side redistribution structure 140. The underfill 160 may be applied in liquid or semi-liquid form and then subsequently cured.

An encapsulant 162 is formed around the various components. After formation, the encapsulant 162 laterally encapsulates the underfill 160 (if present) and the integrated circuit devices 70. The encapsulant 162 may be a molding compound, epoxy, or the like. The encapsulant 162 may be applied by compression molding, transfer molding, or the like, and may be formed over the front-side redistribution structure 140 such that the integrated circuit devices 70 are buried or covered. The encapsulant 162 is further formed in gap regions between the underfill 160 (if present) and/or the integrated circuit devices 70. The encapsulant 162 may be applied in liquid or semi-liquid form and then subsequently cured.

A removal process may optionally be performed on the encapsulant 162 to expose the integrated circuit devices 70. The removal process may include, for example, a planarization process such as a chemical-mechanical polish (CMP), a grinding process, or the like. The upper surfaces of the encapsulant 162 and the integrated circuit devices 70 may be substantially coplanar (within process variations) after the planarization process. The planarization may be omitted, for example, if the integrated circuit devices 70 are already exposed.

In FIG. 8, a carrier substrate de-bonding may be performed to detach (or “de-bond”) the carrier substrate 102 from the back-side redistribution structure 110. In accordance with some embodiments, the de-bonding includes projecting a light such as a UV light on the release layer 104 so that the release layer 104 decomposes under the heat of the light and the carrier substrate 102 can be removed. The remaining structure is a wafer package 100A that will be subsequently attached to a substrate package. The wafer package 100A may be placed on a tape, a carrier substrate, or another suitable support structure (not separately illustrated) for subsequent processing.

UBMs 164 may be formed for subsequent connection to the back-side redistribution structure 110. The UBMs 164 have bump portions on and extending along the major surface of the lower dielectric layer 112 of the back-side redistribution structure 110, and have via portions extending through the lower dielectric layer 112 of the back-side redistribution structure 110 to physically and electrically couple the lower metallization layer 114 of the back-side redistribution structure 110. The UBMs 164 may be formed of the same material as the metallization layers 114, and may be formed by a similar process as the metallization layers 114. In some embodiments, the UBMs 164 may have a different size than the metallization layers 114.

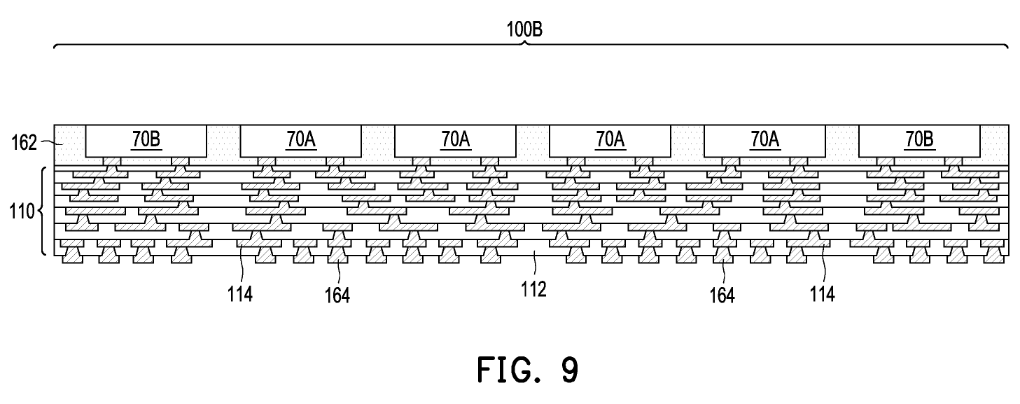

FIG. 9 is a cross-sectional view of a wafer package 100B, in accordance with some embodiments. In this embodiment, the integrated circuit devices 70 are encapsulated in the encapsulant 162, potentially while the integrated circuit devices 70 are disposed on a carrier substrate. The redistribution structure 110 is then formed on the encapsulant 162, with the metallization layers 114 of the redistribution structure 110 being electrically coupled to the integrated circuit devices 70. The UBMs 164 are formed for the redistribution structure 110, such as through an upper dielectric layer 112 of the redistribution structure 110.

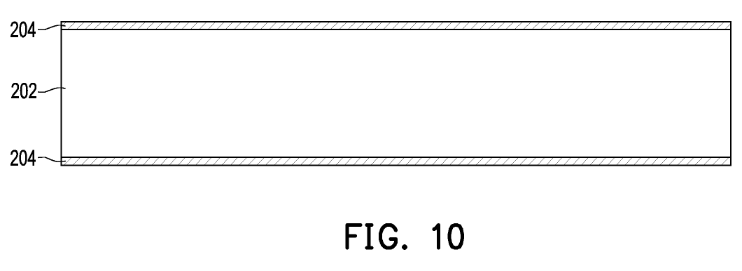

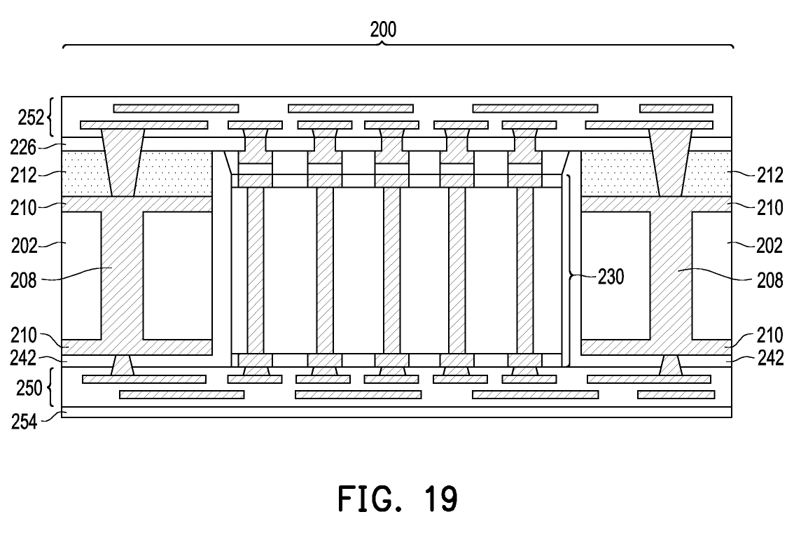

FIGS. 10-19 are cross-sectional views of intermediate stages in the manufacturing of a component substrate 200 (see FIG. 19), in accordance with some embodiments. Multiple component substrates 200 will be packaged in subsequent processing. Each component substrate 200 may be used for interfacing voltage regulator modules (VRMs) or external connectors to integrated circuit devices. In some aspects, a component substrate 200 may be a power distribution board or a connector board. The component substrates 200 may allow direct communication between integrated circuit devices (such as computing devices, interface devices, or the like) and external connectors or VRMs. The component substrate 200 may include an organic core or may be coreless. In some aspects, the component substrate 200 may incorporate devices, such as passive devices. In other aspects, the component substrate 200 may be free of devices.

While the formation of a single component substrate 200 is described, it may be appreciated that multiple component substrates 200 can be manufactured simultaneously, such as on a larger panel or wafer. After fabrication steps are completed, the component substrates 200 may be separated or singulated from the larger panel.

In FIG. 10, a substrate core 202 having seed layers 204 on opposing sides is provided. The substrate core 202 may be a FR-4 or BT resin core. The substrate core 202 may be formed of a pre-impregnated composite fiber (“prepreg”), an insulating film or build-up film, paper, glass fiber, non-woven glass fabric, silicon, or the like. In some embodiments, the substrate core 202 is an organic core formed of organic material(s). In some embodiments, the substrate core 202 is formed of a prepreg including glass fiber and a resin. The seed layers 204 may be one or more layers of copper, titanium, nickel, aluminum, compositions thereof, or the like, and may be deposited or laminated onto opposing sides of the substrate core 202. In some embodiments, the substrate core 202 and seed layers 204 are part of a double-sided copper-clad laminate (CCL) substrate, such as a copper-clad epoxy-impregnated glass-cloth laminate, a copper-clad polyimide-impregnated glass-cloth laminate, or the like.

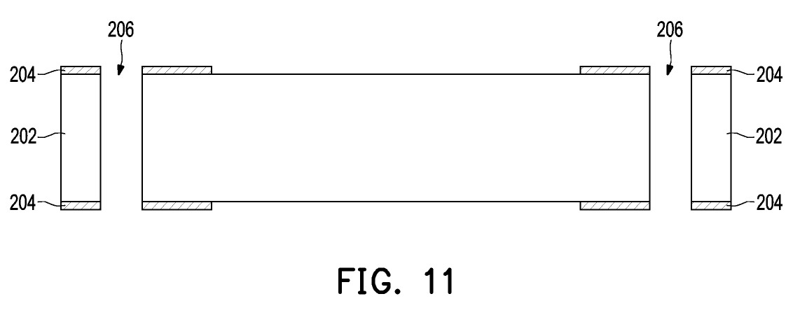

In FIG. 11, openings 206 are formed in the substrate core 202 and seed layers 204. In some embodiments, the openings 206 are formed by laser drilling. Other processes, such as mechanical drilling, may also be used to form the openings 206. The openings 206 may have any top-view shape, such as a polygon, a circle, or the like. A cleaning process may then be performed to clean areas near the openings 206 which may have been smeared with removed material of the substrate core 202. The cleaning process may be a desmear process. The desmearing may be accomplished mechanically (e.g., blasting with a fine abrasive in a wet slurry), chemically (e.g., rinsing with a combination of organic solvents, permanganates, and the like), or by a combination of mechanical and chemical processes.

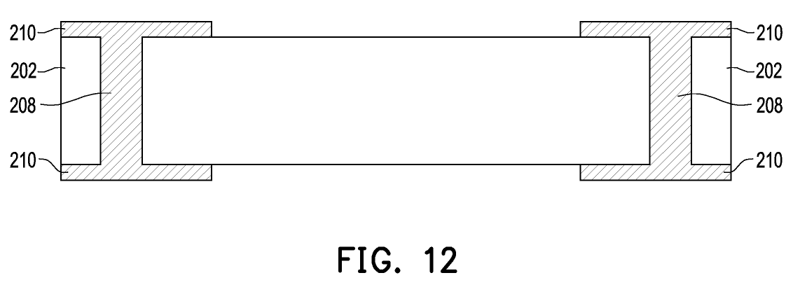

In FIG. 12, conductive vias 208 are formed in the openings 206 and conductive lines 210 are formed on opposite sides the substrate core 202. The conductive vias 208 and conductive lines 210 may be formed of a conductive material such as copper, titanium, tungsten, aluminum, or the like. The conductive vias 208 and conductive lines 210 may be formed of the same material or different materials, and may be formed by a same process or different processes. In some embodiments, the conductive vias 208 are formed with a first process and the conductive lines 210 are formed with a second process. For example, a first plating process, such as electroless plating, may be used to deposit a conductive material in the openings 206, thereby forming the conductive vias 208. In embodiments where electroless plating is used, seed layers may be formed in the openings 206. A second plating process, such as electroplating, electroless plating, or the like, may be performed using the seed layers 204. A photoresist is formed and patterned on the seed layers 204. The photoresist may be formed by spin coating or the like and may be exposed to light for patterning. The pattern of the photoresist corresponds to the conductive lines 210. The patterning forms openings through the photoresist to expose the seed layer. A conductive material is formed in the openings of the photoresist and on the exposed portions of the seed layer. The conductive material may be formed by plating, such as electroplating or electroless plating, or the like. The photoresist and portions of the seed layers 204 on which the conductive material is not formed are removed. The photoresist may be removed by an acceptable ashing or stripping process, such as using an oxygen plasma or the like. Once the photoresist is removed, exposed portions of the seed layers 204 are removed, such as by using an acceptable etching process, such as by wet or dry etching. The remaining portions of the seed layers 204 and conductive material form the conductive lines 210.

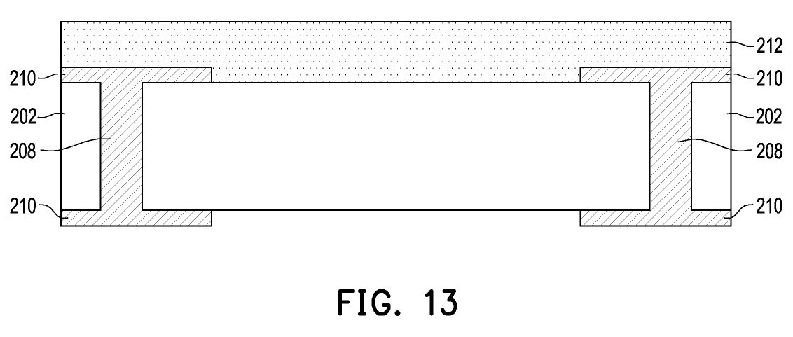

In FIG. 13, an adhesive 212 may be formed on one side of the substrate core 202 and over the conductive lines 210. The adhesive 212 may be applied using various techniques, such as lamination, spin coating, or spray coating. In some aspects, the adhesive 212 may be an adhesive tape that is laminated onto the surface. The adhesive 212 may cover the surface of the substrate core 202 and conductive lines 210 on one side, or it may be selectively applied to specific areas. In some cases, the adhesive 212 may be temporarily applied to provide support during subsequent processing steps and may be removed later.

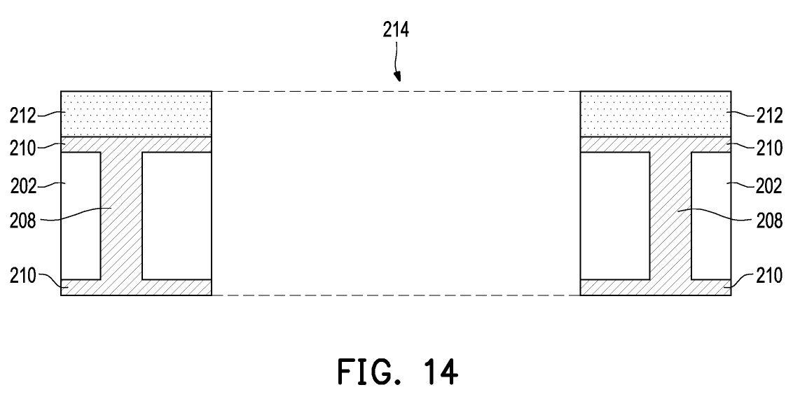

In FIG. 14, an opening 214 may optionally be formed by removing portions of the substrate core 202 and adhesive 212. The removal of material to form the opening 214 may be accomplished by various processes such as mechanical drilling with computer numeric control (CNC), laser cutting, or laser drilling. In embodiments using CNC drilling, a mechanical drill controlled by a computer or controller removes the material from desired locations. Laser-based processes may also be employed for more precise or intricate opening shapes. The size and shape of the opening 214 can be tailored to accommodate specific components or to achieve desired mechanical properties. The opening 214 may extend through both the substrate core 202 and the adhesive 212. The remaining portions of the material form a frame-like structure around the opening 214. The opening 214, if present, may accommodate a passive device, allowing for efficient integration of these components within the component substrate 200.

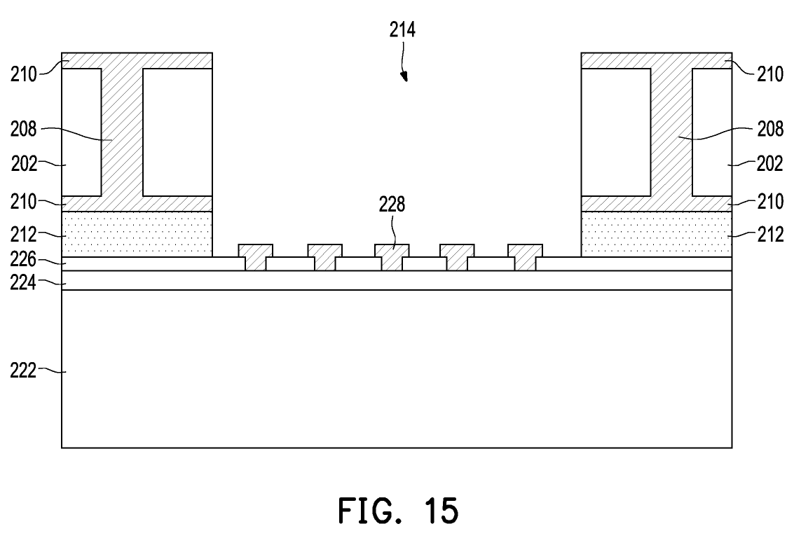

In FIG. 15, a carrier substrate 222 is provided, and a release layer 224 is formed on the carrier substrate 222. The carrier substrate 222 may be a glass carrier substrate, a ceramic carrier substrate, or the like. The carrier substrate 222 may be a wafer.

The release layer 224 may be formed of a polymer-based material, which may be removed along with the carrier substrate 222 from the overlying structure that will be formed in subsequent steps. In some embodiments, the release layer 224 is an epoxy-based thermal-release material, which loses its adhesive property when heated, such as a light-to-heat-conversion (LTHC) release coating. In other embodiments, the release layer 224 may be an ultra-violet (UV) glue, which loses its adhesive property when exposed to UV light. The release layer 224 may be dispensed as a liquid and cured, may be a laminate film laminated onto the carrier substrate 222, or may be the like. The upper surface of the release layer 224 may be leveled and may have a high degree of planarity.

A dielectric layer 226 is formed on the release layer 224. The dielectric layer 226 may be formed of a suitable dielectric material. In some embodiments, the dielectric layer 226 is formed of silicon oxide, silicon nitride, silicon oxynitride, or the like, which may be formed by a suitable deposition process such as CVD, ALD, or the like. In some embodiments, the dielectric layer 226 is formed of a polymer, which may be a photosensitive material such as PBO, polyimide, a BCB-based polymer, or the like, that may be patterned using a lithography mask, which may be formed by spin coating, lamination, CVD, or the like.

The substrate core 202 may be adhered to the dielectric layer 226 using the adhesive 212. The adhesive 212 may be activated by applying pressure, heat, or a combination thereof to bond the substrate core 202 to the dielectric layer 226. In some embodiments, the adhesive 212 may be a thermosetting adhesive that cures and forms a strong bond when exposed to elevated temperatures. The bonding process may be performed using equipment such as a lamination press or a vacuum laminator to ensure uniform pressure and temperature distribution across the bonding interface.

In some embodiments when the substrate core 202 has an opening 214, UBMs 228 may be formed through the dielectric layer 226.The UBMs 228 may be formed before the substrate core 202 is adhered to the dielectric layer 226. Initially, openings may be patterned in the dielectric layer 226 using photolithography and/or etching techniques. A seed layer may then be deposited, covering the openings and the surface of the dielectric layer 226. A photoresist may be applied and patterned to define the shape and size of the UBMs 228. Electroplating or electroless plating processes may be used to form a conductive material (such as copper) in the openings through the photoresist to form the UBMs 228. After plating, the photoresist may be removed, and the excess seed layer may be etched away. In some cases, additional metal layers may be formed on the UBMs 228 to enhance their properties or to facilitate bonding with subsequent components. The resulting UBMs 228 may extend through the dielectric layer 226. During the adhering of the substrate core 202 to the dielectric layer 226, the opening 214 in the substrate core 202 may be aligned with the UBMs 228.

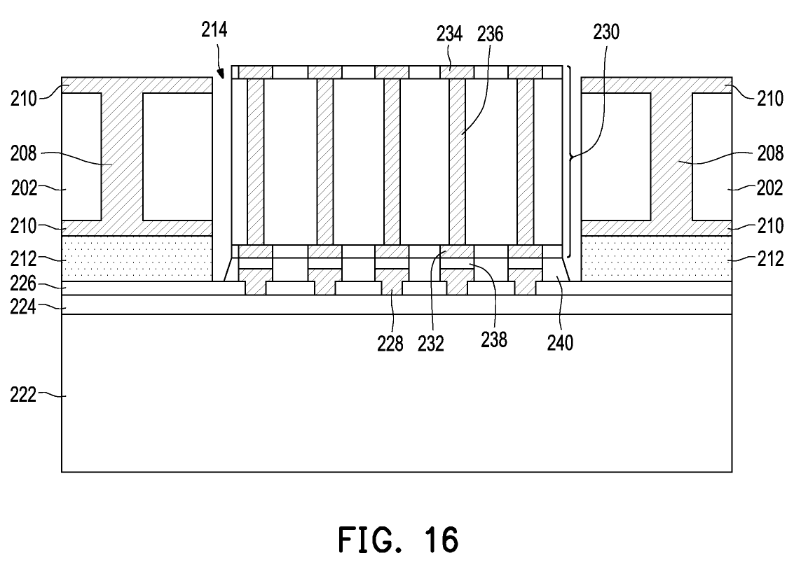

In FIG. 16, a passive device 230 is attached to the underlying structure. The passive device 230 will be included in the component substrate 200 to provide specific electrical characteristics, improve signal integrity, perform power distribution within the substrate, or the like. The passive device 230 may be placed in the opening 214 through the substrate core 202 using, e.g., a pick-and-place tool, however, any other method of placing the passive device 230 may also be utilized. The type and placement of the passive device 230 may be determined by factors such as the intended application of the substrate, performance targets, or space constraints. Although a single passive device 230 is shown and described, it should be appreciated that some embodiments may include multiple passive devices 230 in the component substrate 200.

The passive device 230 may be formed or processed according to applicable manufacturing processes. For example, the passive device 230 may be an IPD that includes one or more passive devices in a main structure. The main structure may include a substrate and/or encapsulant. In the embodiments including a substrate, the substrate may be a semiconductor substrate, such as silicon, doped or undoped, or an active layer of a SOI substrate. The semiconductor substrate may include other semiconductor material, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The passive devices may include a capacitor, resistor, inductor, the like, or a combination thereof. In some embodiments, the passive device 230 is an entirely passive device (e.g., the substrate is free of active or doped regions such that it includes no active devices), such as an integrated voltage regulator (IVR). In some embodiments, the passive device 230 may be partially passive, e.g., may include some active devices. The passive devices may be formed in and/or on the semiconductor substrate and/or within the encapsulant, and may be interconnected by interconnect structures formed by, for example, metallization patterns in one or more dielectric layers on the main structure to form the passive device 230.

The passive device 230 further includes device connectors 232 mechanically and electrically connected to the features of the passive device 230. The device connectors 232 may be, e.g., micro bumps, UBMs, or the like, and may be formed of a conductive material such as copper, aluminum, tungsten, nickel, or alloys thereof, which may be formed by plating or the like. A dielectric material may laterally encapsulate the device connectors 232.

The passive device 230 may further include device connectors 234 formed on an opposite side of the passive device 230 as the device connectors 232. The device connectors 234 may be similar to the device connectors 232 and may be formed of a similar material as the device connectors 232. The device connectors 234 are mechanically and electrically connected to the features of the passive device 230. The device connectors 234 may be formed by, for example, plating, or the like. A dielectric material may laterally encapsulate the device connectors 234.

The passive device 230 may further include through substrate vias (TSVs) 236. The TSVs 236 extend through the substrate of the passive device 230, and connect the device connectors 234 to the device connectors 232. It should be appreciated that each one of the device connectors 232 may not be connected to a respective connector 234. For example, some of the device connectors 232 (e.g., a first subset) may be connected to the passive components of the passive device 230, and others of the device connectors 232 (e.g., a second subset) may be connected to respective device connectors 234 through the TSVs 236. Further, some of the device connectors 232 may be connected to both the passive components of the passive device 230 and a respective connector 234.

The TSVs 236 may be formed by applying and developing a suitable photoresist to the substrate of the passive device 230, and then etching the substrate to form TSV openings. The TSV openings may be filled with, e.g., a liner (not shown), a barrier layer (also not shown), and a conductive material. In an embodiment the liner may be a dielectric material such as silicon nitride, silicon oxide, a dielectric polymer, combinations of these, or the like, formed by a process such as chemical vapor deposition, oxidation, physical vapor deposition, atomic layer deposition, or the like. The barrier layer may include a conductive material such as titanium nitride, although other materials, such as tantalum nitride, titanium, another dielectric, or the like may alternatively be utilized. The barrier layer may be formed using a CVD process, such as PECVD. The barrier layer may be formed so as to contour to the underlying shape of the TSV openings. The conductive material may include copper, although other suitable materials such as aluminum, tungsten, alloys, doped polysilicon, combinations thereof, and the like, may alternatively be utilized. The conductive material may be formed by depositing a seed layer and then electroplating copper onto the seed layer, filling (and potentially overfilling) the TSV openings. Once the TSV openings have been filled, excess barrier layer and excess conductive material outside of the TSV openings may be removed through a planarization process such as a CMP or a grinding process, although any suitable removal process may be used.

Conductive connectors 238 are formed on ends of the device connectors 232 of the passive device 230. The conductive connectors 238 may be, e.g., solder balls, and form solder joints between the device connectors 232 and the UBMs 228. Attaching the passive device 230 to the underlying structure includes forming the conductive connectors 238. Forming the conductive connectors 238 may include forming solder balls and reflowing the solder balls to form connections between the device connectors 232 and the UBMs 228.

An underfill 240 may be filled into the gap between the passive device 230 and the dielectric layer 226 and around the device connectors 232 and the conductive connectors 238. The underfill 240 may be a molding compound, an epoxy, an underfill, a resin, or the like. The underfill 240 provides structural support for the passive device 230, and may be dispensed using capillary forces after the passive device 230 is attached to the UBMs 228. Other processes may be used, such as lamination, compression molding, transfer molding, or the like. A curing step may then be performed to cure and solidify the underfill 240.

In some embodiments, the passive device 230 may be provided on a substrate (not separately illustrated). The substrate may be formed of a semiconductor material or other suitable materials. After attaching the passive device 230 in the opening 214, the substrate may optionally undergo a thinning process. This thinning process may involve techniques such as backside grinding, chemical-mechanical polishing (CMP), or wet etching to reduce the thickness of (or potentially remove) the substrate.

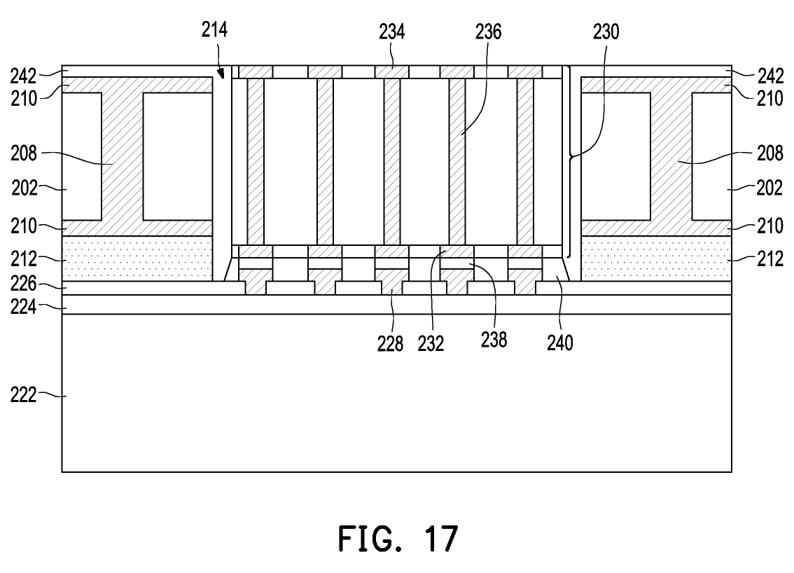

In FIG. 17, a dielectric material 242 is formed over the substrate core 202 and in the opening 214, e.g., around the passive device 230 and the underfill 240. The dielectric material 242 may be formed of Ajinomoto build-up film (ABF), an epoxy, a molding compound, an epoxy molding compound, fiberglass-reinforced resin materials, silica filler, polymer materials, polyimide materials, other build-up materials, other laminates, the like, or combinations thereof. In some cases, the dielectric material 242 may be formed by lamination, where a pre-formed dielectric film is applied using heat and pressure. For example, ABF may be laminated onto the structure using a vacuum lamination process. In other instances, the dielectric material 242 may be applied by spin coating, such as when using liquid epoxy or polyimide materials. Molding compounds or epoxy molding compounds may be applied using compression molding or transfer molding techniques. In some embodiments, the dielectric material 242 may be deposited using chemical vapor deposition (CVD) or plasma-enhanced chemical vapor deposition (PECVD) methods, particularly for certain polymer materials. After application, the dielectric material 242 may undergo curing processes, which may involve heat treatment, UV exposure, or a combination thereof, depending on the specific material used.

After forming the dielectric material 242, it may optionally undergo a thinning process to expose the passive device 230. This thinning process may involve techniques such as chemical-mechanical polishing (CMP), grinding, or etching. In some embodiments, a planarization process may be performed to remove excess material and create a substantially planar surface. The thinning process may be controlled to expose the upper surface of the passive device 230. In some cases, a combination of thinning methods may be employed, such as an initial grinding step followed by a CMP process for improved surface finish. After thinning, the exposed surface of the passive device 230 may be substantially coplanar (within process variations) with the surrounding dielectric material 242.

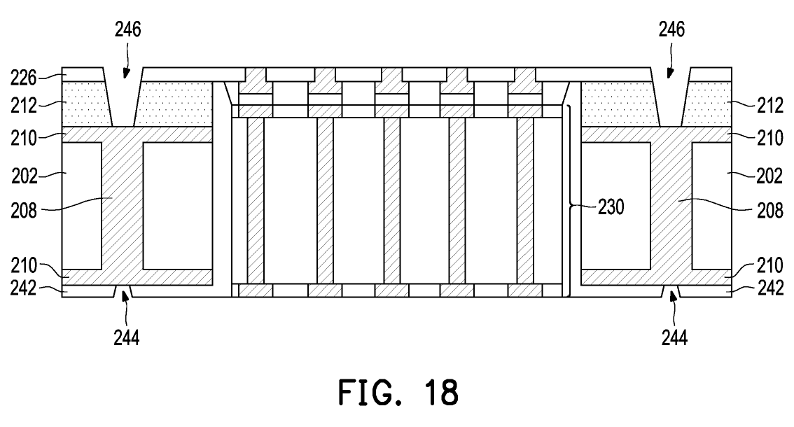

In FIG. 18, a carrier substrate de-bonding may be performed to detach (or “de-bond”) the carrier substrate 222 from the overlying structure. In accordance with some embodiments, the de-bonding includes projecting a light such as a UV light on the release layer 224 so that the release layer 224 decomposes under the heat of the light and the carrier substrate 222 can be removed.

After the substrate de-bonding, openings 244 may be formed through the dielectric material 242, and openings 246 may be formed through the dielectric layer 226 and the adhesive 212. The openings 244, 246 may be formed using various techniques such as photolithography followed by etching, laser drilling, mechanical drilling, or the like. In some cases, a combination of methods may be employed for different layers. The openings 244, 246 expose the conductive lines 210, providing access to these underlying features. Furthermore, a cleaning process may be performed to remove any debris or residues, such as those resulting from the opening formation. This cleaning step may involve techniques such as plasma cleaning, wet chemical cleaning, or mechanical scrubbing to ensure the openings are free of contaminants that could affect subsequent processing or device performance.

In FIG. 19, a first routing structure 250 is formed at one side of the substrate core 202. Also, a second routing structure 252 is formed at another side of the substrate core 202.

The first routing structure 250 may include multiple routing layers including conductive lines, conductive vias, conductive pads, metallization patterns, or redistribution layers. The first routing structure 250 may include a plurality of routing layers embedded within multiple insulating layers. The routing layers may include one or more layers of conductive materials such as copper, nickel, aluminum, or combinations thereof. The insulating layers may be formed of materials like build-up material, ABF, prepreg material, laminate material, oxides, nitrides, or polymers. In some cases, the outermost routing layer of the first routing structure 250 may include bonding pads to allow for physical and electrical connections to other package components. These bonding pads may include conductive pads, conductive pillars, solder bumps, or under-bump metallizations (UBMs).

The second routing structure 252 may include multiple routing layers including conductive lines, conductive vias, conductive pads, metallization patterns, or redistribution layers. The second routing structure 252 may include a plurality of routing layers embedded within multiple insulating layers. The routing layers may include one or more layers of conductive materials such as copper, nickel, aluminum, or combinations thereof. The insulating layers may be formed of materials like build-up material, ABF, prepreg material, laminate material, oxides, nitrides, or polymers. In some cases, the outermost routing layer of the second routing structure 252 may include bonding pads to allow for physical and electrical connections to other package components. These bonding pads may include conductive pads, conductive pillars, solder bumps, or under-bump metallizations (UBMs).

The first routing structure 250 and the second routing structure 252 may be coupled to the conductive lines 210 by vias formed in the openings 244, 246, respectively. In this way, the conductive vias 208 in the substrate core 202 may electrically connect the first routing structure 250 to the second routing structure 252. Additionally, in some embodiments, the first routing structure 250 and the second routing structure 252 may be electrically coupled to the passive device 230. This configuration may allow for efficient routing of electrical signals between different layers of the package and to various components, including the passive device 230.

The first routing structure 250 and the second routing structure 252 may be formed using similar processes. These processes may involve building up alternating layers of dielectric material and conductive features. Conductive features, including traces, vias, and pads, may be formed within and between dielectric layers using techniques such as photolithography, etching, and plating. Each layer may be formed sequentially, with vias providing electrical connections between different metal layers. The process may be repeated multiple times to create the desired number of routing layers.

A solder resist layer 254 may be formed on the outer surface of the first routing structure 250. The solder resist layer 254 may be applied as a liquid or dry film using techniques such as screen printing, spray coating, or lamination. After application, the solder resist layer 254 may be patterned using photolithography to create openings that expose underlying conductive pads or features where electrical connections are desired. The patterned solder resist layer 254 may then undergo curing processes, which may involve heat treatment, UV exposure, or a combination thereof, depending on the specific material used. This solder resist layer 254 helps to protect the underlying circuitry from environmental factors and prevents solder bridges during subsequent assembly processes.

Subsequently, the component substrate 200 may be singulated from adjacent component substrates. The singulation process may involve sawing, laser cutting, or mechanical separation to divide a larger substrate into smaller, discrete component substrates. The resulting individual component substrate 200 may be included in a substrate package, where it can be combined with other components to form a more complex assembly.

After its individual processing is complete, testing may be performed on the component substrate 200. For example, probe testing may be performed on the component substrate 200 to ascertain whether the component substrate 200 is a known good substrate. This testing may involve using automated test equipment with probe cards to make temporary electrical connections to test pads or terminals on the component substrate 200. The testing may include electrical continuity checks, resistance measurements, capacitance measurements, and functional tests to verify the integrity of conductive paths, insulation between layers, and proper operation of any embedded passive components. In some cases, the testing may also involve thermal cycling or stress tests to ensure reliability under various operating conditions. Thus, only component substrates 200, which are known good substrates, undergo subsequent processing, and substrates which fail the probe testing are not packaged.

Other variations of the component substrates 200 are contemplated. In some embodiments, devices (including passive devices) may be omitted from a component substrate 200. Such a component substrate 200 may include a substrate core 202 without devices disposed thereon. This configuration may provide a simpler structure that can still function as part of an overall package assembly. In some embodiments, a component substrate 200 may be a coreless substrate. A coreless substrate may refer to a substrate that does not have a solid substrate core, such as a FR-4 or BT resin core. Instead, it is built up of alternating dielectric and conductive layers. Coreless substrates may be formed by sequentially forming and patterning dielectric and conductive materials on a temporary carrier, which is later removed. This type of substrate may offer advantages such as reduced thickness and improved electrical performance in certain applications. The coreless design may allow for finer pitch interconnects and may facilitate easier integration with other package components. Additionally, coreless substrates may provide better thermal management due to the absence of a thick core layer.

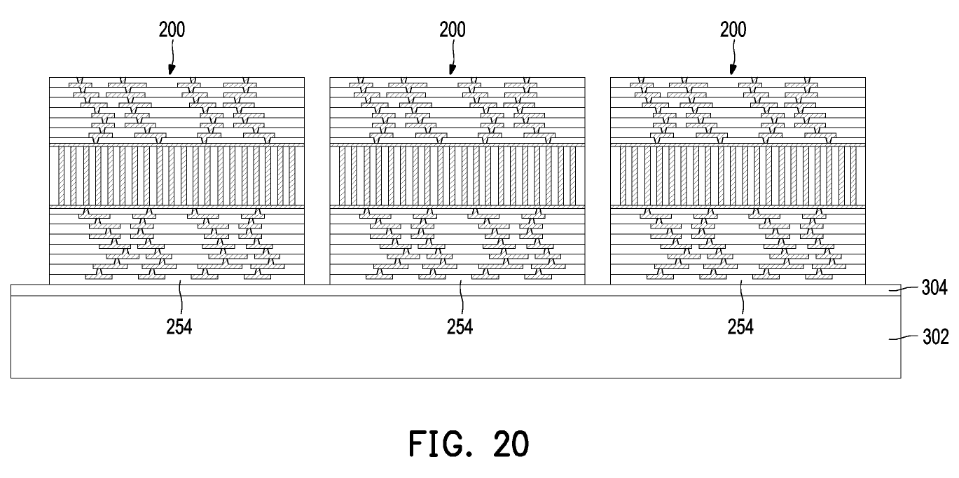

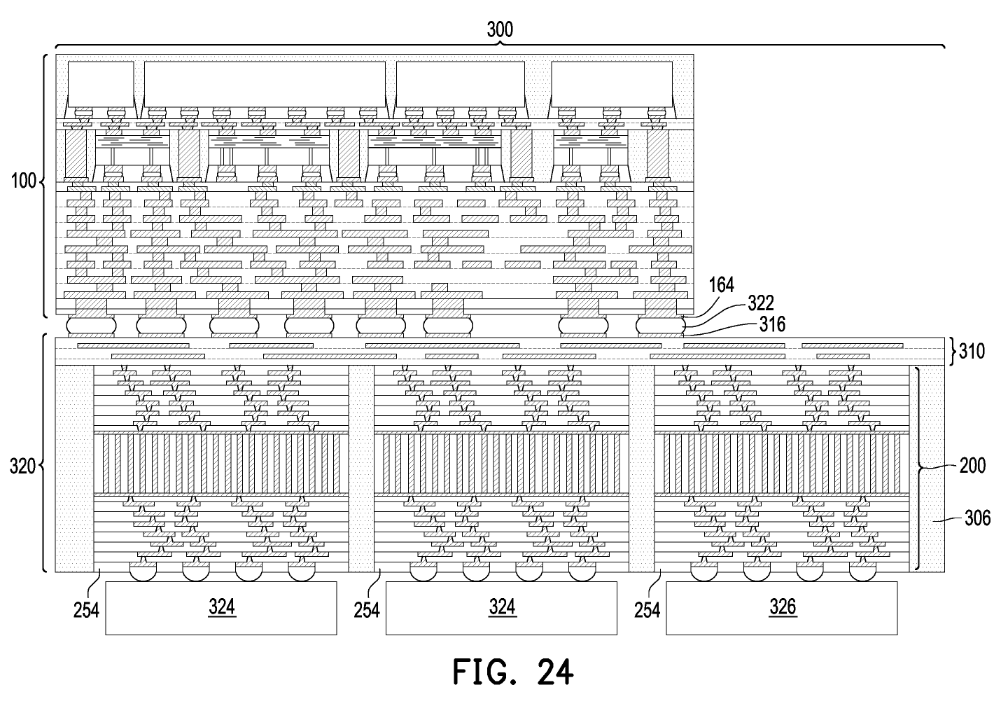

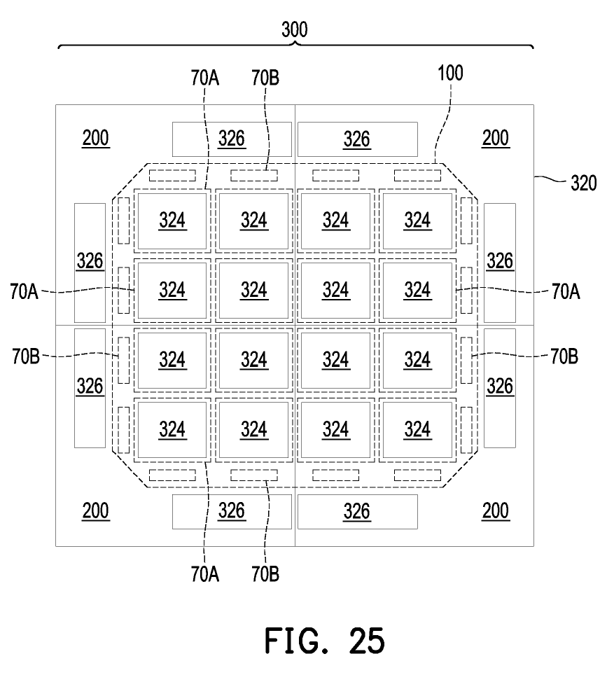

FIGS. 20-25 are cross-sectional views of intermediate stages in the manufacturing of a system package 300 (see FIGS. 24-25), in accordance with some embodiments. FIGS. 20-24 are cross-sectional views, where only one portion (e.g., half) of the system package 300 is shown for illustration clarity. FIG. 25 is a top-down view.

In FIG. 20, a carrier substrate 302 is provided, and a release layer 304 is formed on the carrier substrate 302. The carrier substrate 302 may be a glass carrier substrate, a ceramic carrier substrate, or the like. The carrier substrate 302 may be a wafer.

The release layer 304 may be formed of a polymer-based material, which may be removed along with the carrier substrate 302 from the overlying structure that will be formed in subsequent steps. In some embodiments, the release layer 304 is an epoxy-based thermal-release material, which loses its adhesive property when heated, such as a light-to-heat-conversion (LTHC) release coating. In other embodiments, the release layer 304 may be an ultra-violet (UV) glue, which loses its adhesive property when exposed to UV light. The release layer 304 may be dispensed as a liquid and cured, may be a laminate film laminated onto the carrier substrate 302, or may be the like. The upper surface of the release layer 304 may be leveled and may have a high degree of planarity.

A plurality of component substrates 200 are then attached to the release layer 304. A desired type and quantity of component substrates 200 are placed adjacent one another. In some embodiments, the component substrates 200 include one or more power distribution substrates and one or more connector substrates. The component substrates 200 may be placed on the release layer 304 using, e.g., a pick-and-place tool. In some embodiments, the component substrates 200 are placed with their solder resist layers 254 facing the carrier substrate 302.

Although not separately illustrated, it should be appreciated that some or all of the component substrates 200 may include passive devices (previously described for FIG. 16). Furthermore, one subset of the component substrates 200 (such as power distribution substrates) may include devices while another subset of the component substrates 200 (such as connector substrates) may be free of devices.

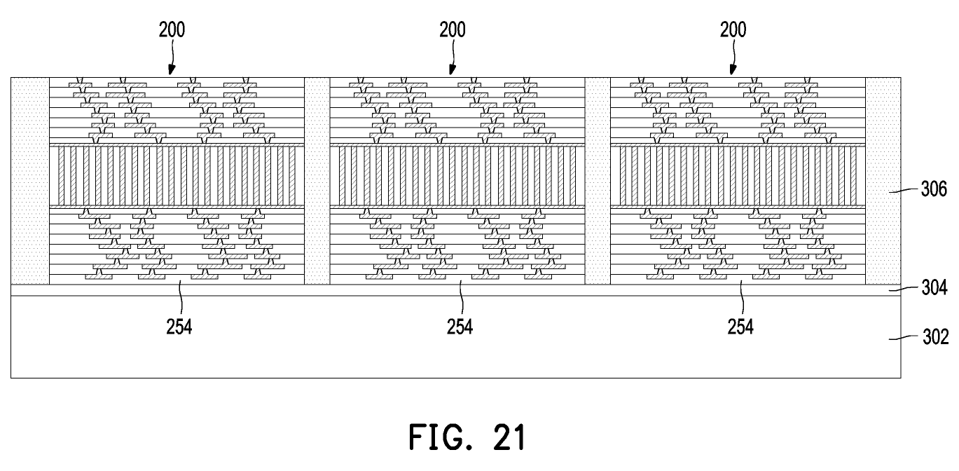

In FIG. 21, an encapsulant 306 is formed on and around the various components. After formation, the encapsulant 306 may encapsulate the component substrates 200. The encapsulant 306 may be a molding compound, epoxy, or the like, and may be applied by compression molding, transfer molding, or the like. The encapsulant 306 may be applied in liquid or semi-liquid form and then subsequently cured. In some embodiments, the encapsulant 306 is formed over the carrier substrate 302 such that the component substrates 200 are buried or covered, and a planarization process may then be performed on the encapsulant 306 to expose the component substrates 200. The planarization process may be, for example, a chemical-mechanical polish (CMP), a grinding process, or the like. The upper surfaces of the encapsulant 306 and the component substrates 200 may be substantially coplanar (within process variations) after the planarization process.

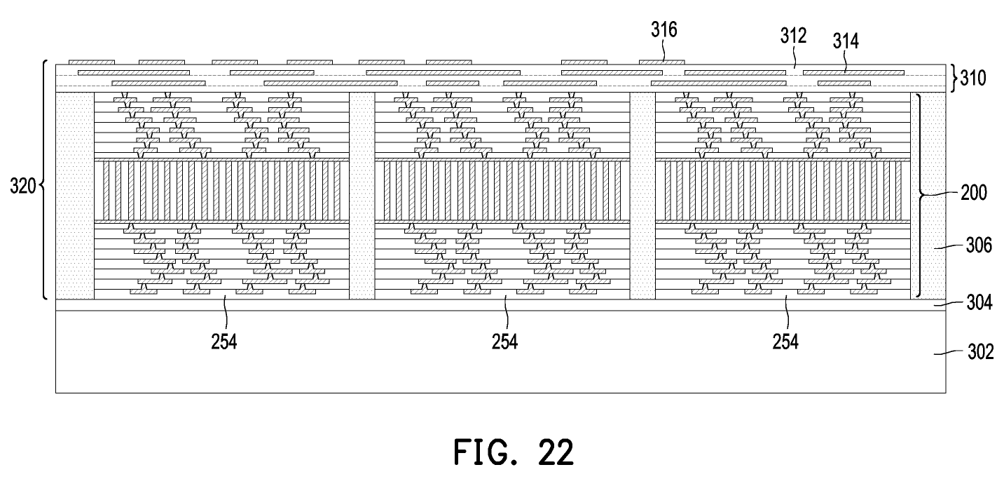

In FIG. 22, a redistribution structure 310 is formed over the encapsulant 306 and the component substrates 200. The redistribution structure 310 includes dielectric layers 312 and metallization layer(s) 314 (sometimes referred to as redistribution layers or redistribution lines) among the dielectric layers 312. Thus, the redistribution structure 310 includes metallization layer(s) 314 separated from each other by respective dielectric layers 312. The metallization layer(s) 314 of the redistribution structure 310 are connected to the conductive features of the upper routing structures of the component substrates 200.

In some embodiments, the dielectric layers 312 are formed of a polymer, which may be a photosensitive material such as PBO, polyimide, a BCB-based polymer, or the like, that may be patterned using a lithography mask. In other embodiments, the dielectric layers 312 are formed of a nitride such as silicon nitride, an oxide such as silicon oxide, or the like. The dielectric layers 312 may be formed by spin coating, lamination, CVD, the like, or a combination thereof. After a dielectric layer 312 is formed, it may be patterned to expose underlying conductive features of the component substrates 200 and/or the metallization layer(s) 314. The patterning may be by any acceptable process, such as by exposing the dielectric layers 312 to light when they are formed of photosensitive material, or by etching using, for example, an anisotropic etch. If the dielectric layers 312 are formed of a photosensitive material, the dielectric layers 312 may be developed after the exposure.

The metallization layer(s) 314 each include conductive vias and/or conductive lines. The conductive vias extend through respective dielectric layers 312, and the conductive lines extend along respective dielectric layers 312. As an example to form a metallization layer 314, a seed layer (not separately illustrated) is formed over the respective underlying features. For example, the seed layer may be formed on a respective dielectric layer 312 and in any openings through the respective dielectric layer 312. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 314. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 314 of the redistribution structure 310.

The redistribution structure 310 is illustrated as an example. More or fewer dielectric layers 312 and metallization layer(s) 314 than illustrated may be formed by performing the previously described steps any desired quantity of times.

Other variations of the redistribution structure 310 are contemplated. For example, some of the dielectric layers 312 may be formed of an encapsulant, such as a molding compound, epoxy, or the like. A metallization layer 314 may be formed by plating a conductive via from a conductive line. A dielectric layer 312 may be formed by encapsulating that metallization layer 314. Any desired stack of materials may be used for the dielectric layers 312.

Under-bump metallizations (UBMs) 316 may be formed through the upper dielectric layer 312 of the redistribution structure 310. The UBMs 316 are physically and electrically coupled to the upper metallization layer 314 of the redistribution structure 310. The UBMs 316 each include conductive vias and conductive bumps. The conductive vias extend through the upper dielectric layer 312, and the conductive bumps extend along the upper dielectric layer 312. The UBMs 316 may be formed of the same material(s) as the metallization layer(s) 314. In some embodiments, the UBMs 316 have a different size than the metallization layer(s) 314.

The structure formed over the carrier substrate 302 at this step of processing is a substrate package 320. The substrate package 320 is a reconstituted wafer including the multiple component substrates 200 in the encapsulant 306, with the redistribution structure 310 disposed thereon.

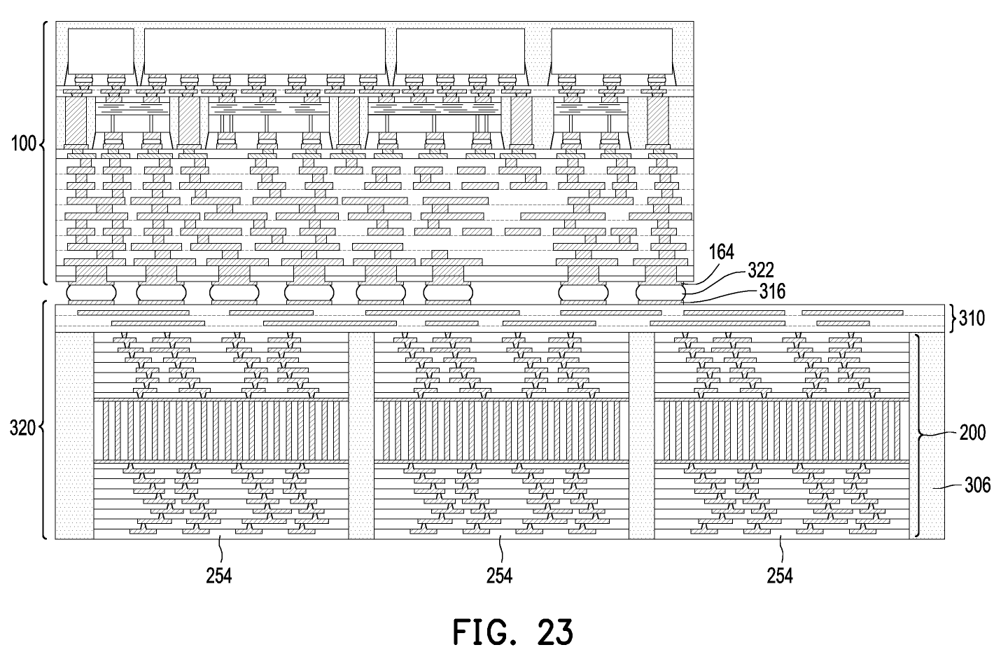

In FIG. 23, a wafer package 100 is attached to the redistribution structure 310 of the substrate package 320. In this example, the wafer package described for FIG. 8 is attached. Alternatively, the wafer package described for FIG. 9 or another wafer package may be attached to the redistribution structure 310.

In the illustrated embodiment, the wafer package 100 is attached to the substrate package 320 with solder bonds, such as with conductive connectors 322. The conductive connectors 322 may be formed of a conductive material that is reflowable, such as solder, copper, aluminum, gold, nickel, silver, palladium, tin, the like, or a combination thereof. In some embodiments, the conductive connectors 322 are formed by initially forming a layer of solder through methods such as evaporation, electroplating, printing, solder transfer, ball placement, or the like. Once a layer of solder has been formed, a reflow may be performed in order to shape the conductive connectors 322 into desired bump shapes. Attaching the wafer package 100 to the redistribution structure 310 may include placing the wafer package 100 on the redistribution structure 310 and reflowing the conductive connectors 322. The wafer package 100 may be placed on the redistribution structure 310 using, e.g., a pick-and-place tool. The conductive connectors 322 are reflowed to attach the UBMs 164 of the wafer package 100 to the UBMs 316 of the redistribution structure 310, thereby electrically connecting the redistribution structure 310 to the wafer package 100. In another embodiment, the wafer package 100 is attached to the substrate package 320 with direct bonds.

After the wafer package 100 is attached to the substrate package 320, a carrier substrate de-bonding may be performed to detach (or “de-bond”) the carrier substrate 302 from the substrate package 320. In accordance with some embodiments, the de-bonding includes projecting a light such as a UV light on the release layer 304 so that the release layer 304 decomposes under the heat of the light and the carrier substrate 302 can be removed. The removal of the carrier substrate 302 may expose the lower surfaces of the component substrates 200 (of the substrate package 320) for subsequent attachment of additional components to the substrate package 320.

In FIG. 24, voltage regulators 324 and external connectors 326 are attached to the side of the substrate package 320 opposite the wafer package 100. These components may allow for efficient power distribution and external connectivity to the resulting system package. The placement of these components on the opposite side of the substrate package 320 from the wafer package 100 may facilitate easier system maintenance or upgrades.

The voltage regulators 324 may be power management devices for maintaining stable voltage levels for the various components in the wafer package 100. These regulators may be implemented in various forms, such as integrated circuit dies, discrete components on circuit boards, multi-chip modules, or the like. In some embodiments, the voltage regulators 324 may be system-in-package (SiP) devices that incorporate multiple functions, including power regulation, current sensing, and thermal management. The voltage regulators 324 may also be implemented as switching regulators, linear regulators, or a combination of both, depending on the specific power requirements of the system.

The external connectors 326 may serve as interfaces for connecting the components of the system (e.g., the wafer package 100) to external systems or components. These connectors may be implemented as ribbon cable receptors, flexible printed circuit receptors, or other types of high-density interconnects. In some embodiments, the external connectors 326 may support various communication protocols, such as PCI-Express, USB, InfiniBand, custom high-speed interfaces, or the like. The design of these connectors may allow for easy attachment and detachment of external cables or modules, facilitating integration of the resulting system package with an external system.

The component substrates 200 electrically connect the voltage regulators 324 to the integrated circuit devices in the wafer package 100. Similarly, the component substrates 200 electrically connect the external connectors 326 to the integrated circuit devices in the wafer package 100, enabling communication between the integrated circuit devices and external systems.

The voltage regulators 324 and external connectors 326 may be attached to the substrate package 320 using reflowable connectors, which connect the components to the lower routing structures of the component substrates 200. The reflowable connectors may be formed of a conductive material such as solder, copper, aluminum, gold, nickel, silver, tin, or combinations thereof. In some embodiments, the reflowable connectors may be solder balls, metal pillars, controlled-collapse chip connection (C4) bumps, or the like. The reflowable connectors may be formed by initially forming openings in the solder resist layers 254 of the component substrates 200. Next, a conductive material may be formed in the openings by methods such as evaporation, electroplating, printing, solder transfer, or ball placement. After forming the conductive material, a reflow process may be performed to shape the material into the desired connector structures.

Attaching the voltage regulators 324 and external connectors 326 to the substrate package 320 may involve placing the components on the substrate package 320 (e.g., the reflowable connectors extending through the solder resist layers 254) using a pick-and-place technique, followed by a reflow process to create reliable electrical and mechanical connections with the lower routing structures of the component substrates 200. In some embodiments, a jig may be used to facilitate the attachment process. The jig may include adjustable portions that can be positioned to support the substrate package 320 and attached components during placement and reflow. After the voltage regulators 324 and external connectors 326 are attached, the jig may be removed. The remaining structure is a system package 300, which may be a SoW. The SoW is a complete computing system that includes computing sites (including the devices of the wafer package 100 and associated voltage regulators 324) and connecting sites (including the external connectors 326).

In some embodiments, the voltage regulators 324 and external connectors 326 may have a one-to-one correspondence with the component substrates 200, where each component substrate 200 is associated with a single voltage regulator 324 or external connector 326. In other embodiments, multiple voltage regulators 324 or external connectors 326 may be attached to a single component substrate 200, allowing for more flexible power distribution and connectivity options. For example, multiple voltage regulators 324 may be attached to a power distribution substrate while multiple external connectors 326 may be attached to a connector substrate.

The component substrates 200 may include dedicated power distribution substrates for the voltage regulators 324 and separate, dedicated connector substrates for the external connectors 326. These different types of component substrates 200 may have distinct structures, functionalities, and integrated devices tailored to their specific roles. For instance, power distribution substrates may incorporate features optimized for efficient power delivery, while connector substrates may be designed with high-speed signal routing and impedance matching considerations. The power distribution substrates may have different structures as compared to the connector substrates. In some aspects, the power distribution substrates may include devices, while the connector substrates may be free of devices.

The substrate package 320 may incorporate any number of component substrates 200. For example, the substrate package 320 may include four component substrates 200 arranged in a 2x2 grid configuration. The number of component substrates 200 may be selected based on factors such as the desired functionality, power requirements, and connectivity needs of the system package 300. This modular approach may provide flexibility in system design and allow for customization of the substrate package 320 to meet various application requirements.

While each component substrate 200 may be smaller than the wafer package 100, the substrate package 320 (including the multiple component substrates 200) is larger than the wafer package 100. The outer perimeter of the substrate package 320 extends beyond the outer perimeter of the wafer package 100. In other words, the width of the substrate package 320 may be greater than the width of the wafer package 100 in a cross-sectional view, while the width of each component substrate 200 may be less than the width of the wafer package 100 in the cross-sectional view. The larger size of the substrate package 320 relative to the wafer package 100 may allow for additional routing features and external connections to be incorporated around the periphery of the wafer package 100, including those which would overhang the edge of the wafer package 100 if they were directly attached thereto.

The portions of the substrate package 320 that extend beyond the perimeter of the wafer package 100 may be utilized for attaching the external connectors 326. These extended regions may provide dedicated areas for incorporating high-density interconnects, such as ribbon cable receptors, flexible printed circuit receptors, or other types of connectors that facilitate communication with external systems or components. Meanwhile, the internal portions of the substrate package 320 that overlap with the wafer package 100 may be used for attaching the voltage regulators 324. This arrangement may allow for efficient power distribution to the components within the wafer package 100, as the voltage regulators 324 can be positioned in close proximity to the devices they support.

Referring to FIG. 25, the system package 300 is shown in more detail. While all of the subsequently discussed components are shown in FIG. 25 for illustration clarity, it should be appreciated that the wafer package 100 may be positioned below the substrate package 320 (e.g., going into the page), and the voltage regulators 324 and external connectors 326 may be positioned above the wafer package 100 (e.g., coming out of the page).

The voltage regulators 324 may be positioned directly over the wafer package 100, with each voltage regulator 324 corresponding to a computing device 70A (e.g., a logic die, memory die, combination thereof, etc.) of the wafer package 100. Each voltage regulator 324 may provide power for the wafer package 100 through the routing features in the substrate package 320. Positioning the voltage regulators 324 close to the devices of the wafer package 100 may reduce power loss and/or voltage drops.

The external connectors 326 may be located at the periphery of the substrate package 320, positioned along its edges. This placement may facilitate easier connections to external components or systems, as the external connectors 326 are readily accessible at the outer boundaries of the system package 300.

The interface devices 70B are situated at the edge of the wafer package 100, potentially in close proximity to the external connectors 326. In the top-down view, the interface devices 70B are positioned between the external connectors 326 and the array of voltage regulators 324 and computing devices 70A. The interface devices 70B may be positioned to reduce signal path lengths to the external connectors 326. The interface devices 70B may mediate communications between the external connectors 326 and the computing devices 70A, performing signal routing and data transfer within the system package 300.

The layout of components within the system package 300 may be arranged with respect to the perimeter of the wafer package 100, in the top-down view. The voltage regulators 324 may be positioned within the perimeter of the wafer package 100. Meanwhile, the external connectors 326 may be positioned outside the perimeter of the wafer package 100. Other variations are possible.

The substrate package 320 and the wafer package 100 may have different shapes in the top-down view. The wafer package 100 may be circle-shaped (truncated or non-truncated) while the substrate package 320 may be square-shaped.

Furthermore, in the example of FIG. 25, the components of the system package 300 are symmetrically laid out. In another embodiment, an asymmetrical layout may be utilized. The layout of the system package 300 may be determined based on specific application needs.

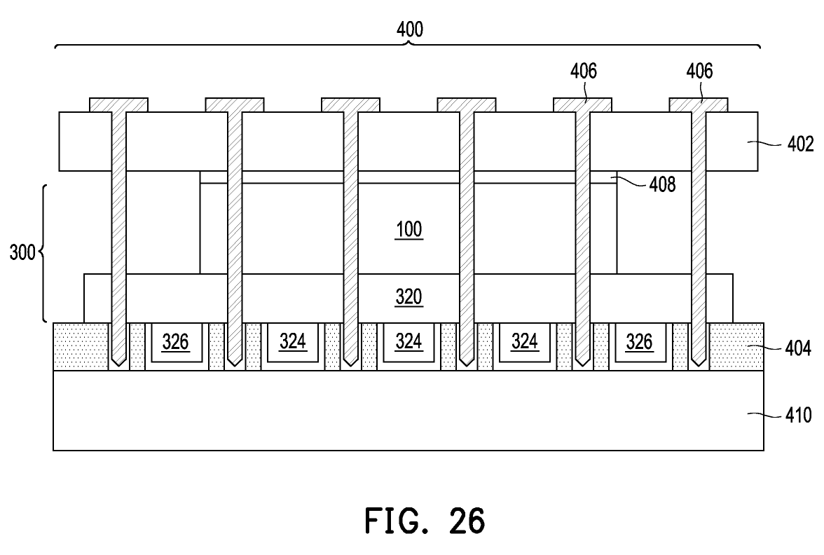

FIG. 26 is a cross-sectional view of a system-on-wafer assembly 400, in accordance with some embodiments. The system-on-wafer assembly 400 is formed by securing the system package 300 of FIGS. 24-25 between a thermal module 402 and a frame 404. Warpage of the system package 300 may be reduced by securing the system package 300 between the thermal module 402 and the frame 404. In this embodiment, the width of the wafer package 100 is less than the width of the substrate package 320.

The thermal module 402 may be attached to the bottom of the system package 300, at the same side as the wafer package 100. The thermal module 402 is in thermal contact with the wafer package 100. The thermal module 402 may be a heat sink, heat spreader, cold plate, or similar device designed to manage heat dissipation from the components within the system-on-wafer assembly 400. In some embodiments, the thermal module 402 may have a recess to accommodate the wafer package 100. The recesses may allow the thermal module 402 to make closer contact with heat-generating components of the wafer package 100 while providing space for other protruding elements.

The frame 404 is attached to the top of the system package 300, providing structural support and protection for the internal components, such as the voltage regulators 324 and external connectors 326. The frame 404 is a rigid support that may be formed of a material with a high stiffness, such as a metal, e.g., steel, titanium, cobalt, or the like. In some embodiments, the system-on-wafer assembly 400 may include a spacer (not separately illustrated) between the frame 404 and the substrate package 320. The frame 404 (or spacer, if present) physically engages portions of the substrate package 320. The frame 404 has recesses and/or openings that accommodate the voltage regulators 324 and external connectors 326 at this side of the substrate package 320. The frame 404 may also have openings that accommodate connectors (e.g., wires, cables, etc.) from external systems to the external connectors 326.

Bolts 406 may be used to fasten the system package 300 between the thermal module 402 and the frame 404. The bolts 406 may extend into or through the thermal module 402 and/or the frame 404. In particular, the thermal module 402 and the frame 404 may include corresponding bolt holes, which may be threaded or unthreaded. During the assembly process, bolt holes may be drilled in the substrate package 320 and the wafer package 100 to accommodate the bolts 406. When the bolt holes are threaded, the bolts 406 may be directly screwed into the threaded holes. When the bolt holes are unthreaded, the bolts 406 may be secured with fasteners (not separately illustrated) such as nuts, washers, or the like. The bolts 406 secure the components of the system-on-wafer assembly 400 together, providing structural integrity. The bolts 406 (or fasteners thereon) may be tightened to a specific torque to apply a desired clamping force across the system-on-wafer assembly 400, which may reduce assembly warpage.

In some embodiments, a thermal interface material 408 may be applied between the thermal module 402 and the wafer package 100. The thermal interface material 408 enhances thermal conductivity between the wafer package 100 and the thermal module 402, improving overall heat dissipation in the system-on-wafer assembly 400. The thermal interface material 408 may be a film including materials such as indium or other thermally conductive substances.

In some embodiments, a cooling system 410 may be attached to the frame 404 of the system-on-wafer assembly 400. The cooling system 410 may be part of an external system designed to enhance thermal management of the assembly. This cooling system may take various forms, such as a liquid cooling system that circulates coolant through channels or pipes integrated into or attached to the frame 404. For example, the cooling system 410 may include a water cooling setup with a pump, radiator, and reservoir. Alternatively, the cooling system 410 may be an air cooling system with fans or blowers that force air through heat sinks or fins attached to the frame 404. The integration of the cooling system 410 may allow for more efficient heat dissipation from the components within the system-on-wafer assembly 400, potentially enabling higher performance or more compact designs.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

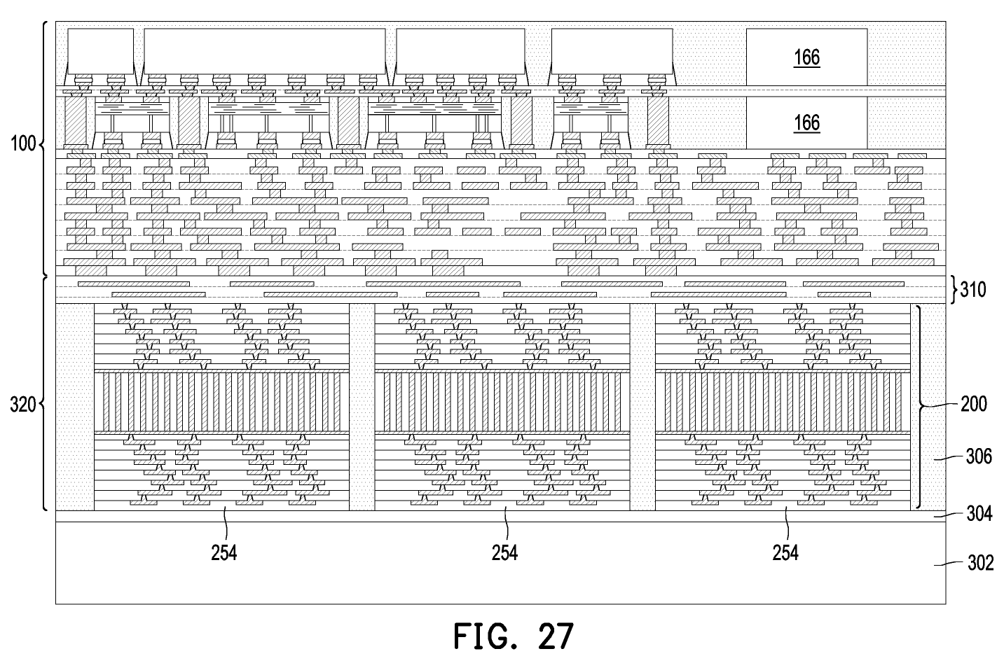

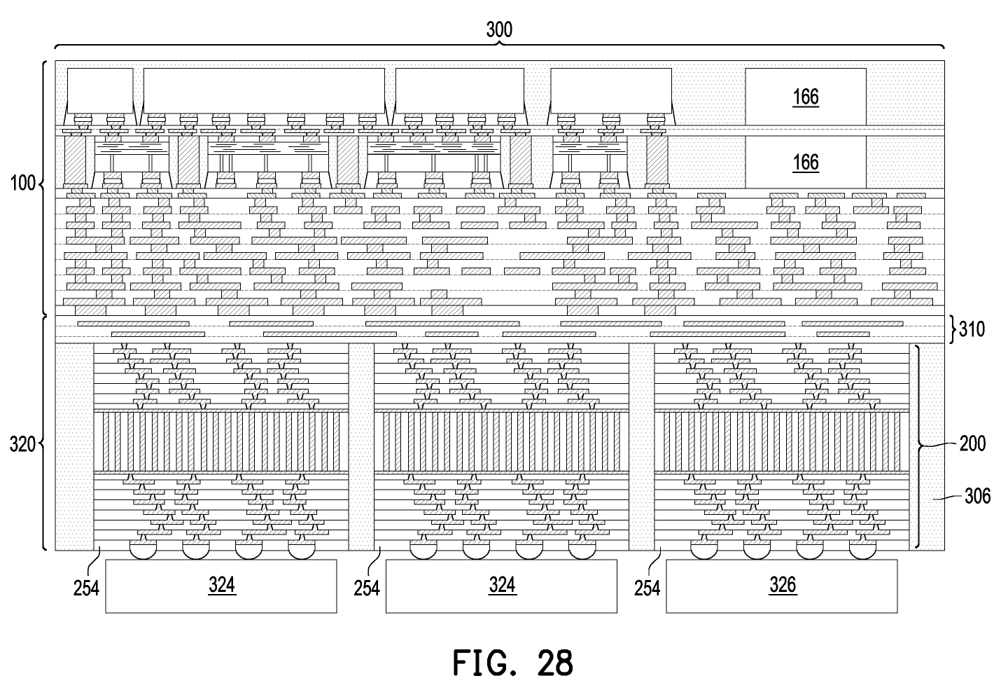

FIGS. 27-28 are views of intermediate stages in the manufacturing of a substrate package, in accordance with some embodiments. This embodiment is similar to the embodiment of FIGS. 20-25, except the wafer package 100 is formed after (and over) the substrate package 320. FIGS. 27-28 are cross-sectional views, where only one portion (e.g., half) of the system package 300 is shown for illustration clarity.

In FIG. 27, the structure of FIG. 22 is formed or obtained, except the UBMs 316 may be omitted. Instead, the wafer package 100 is formed on the redistribution structure 310. The wafer package 100 may be formed by, e.g., a similar process as that described for FIGS. 3-8, except the back-side redistribution structure 110 may be built up over the redistribution structure 310 instead of a separate carrier substrate. This may reduce warpage from the formation of the back-side redistribution structure 110. Furthermore, UBMs may be omitted from the back-side redistribution structure 110; instead the metallization layers 114 of the back-side redistribution structure 110 may be directly connected to the metallization layers 314 of the redistribution structure 310. This direct connection between redistribution structures may allow for a more compact overall package structure in some cases.

In some embodiments, the wafer package 100 may include dummy dies 166 in addition to functional integrated circuit devices. These dummy dies 166 may be positioned within the wafer package 100 at desired locations, potentially overlapping with areas where the external connectors 326 are attached to the substrate package 320. The inclusion of the dummy dies 166 may serve various purposes, such as maintaining structural uniformity, improving thermal distribution, reducing warpage, or enhancing the overall mechanical stability of the wafer package 100. In cases where the dummy dies 166 overlap with the external connectors 326 and/or connector substrates, they may provide additional support or act as spacers, potentially facilitating more reliable connections between the wafer package 100 and the substrate package 320.

In FIG. 28, after the wafer package 100 is formed, the carrier substrate 302 may be removed. Similar processing as previously described may be performed to complete the system package 300.

In this embodiment, the wafer package 100 and the substrate package 320 may have substantially the same width. This configuration may allow for efficient utilization of space within the system package 300. Both the voltage regulators 324 and external connectors 326 may be disposed inside the perimeter of the wafer package 100 in a top-down view. However, the external connectors 326 may still be positioned beyond the integrated circuit devices of the wafer package 100. The dummy dies 166 included in the wafer package 100 overlap with the external connectors 326, potentially providing additional mechanical support or acting as spacers.

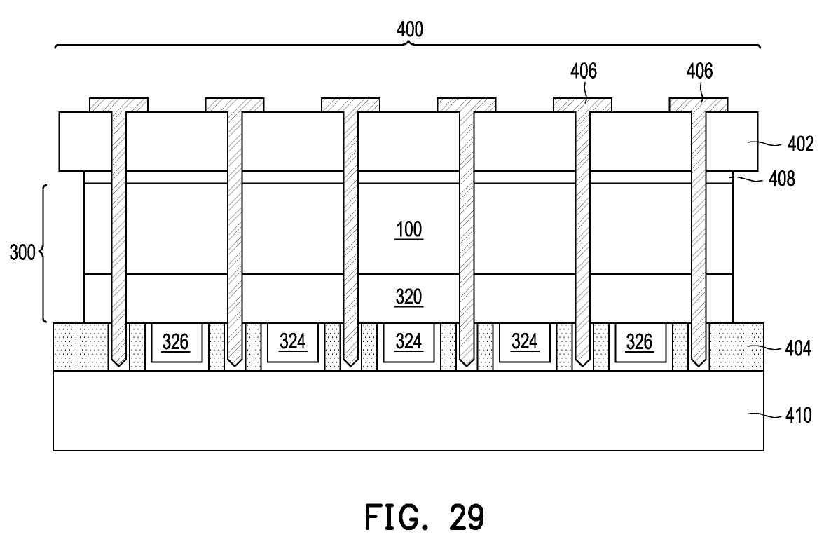

FIG. 29 is a cross-sectional view of a system-on-wafer assembly 400, in accordance with some embodiments. The system-on-wafer assembly 400 is formed by securing the system package 300 of FIG. 28 between a thermal module 402 and a frame 404, similar to the embodiment of FIG. 26. In this embodiment, the width of the wafer package 100 is equal to width of the substrate package 320.

Embodiments may achieve advantages. By implementing the substrate package 320 with component substrates 200, the peripheral regions of the substrate package 320 can be effectively used for attachment of the external connector 326. This approach enables the wafer package 100 to accommodate a greater number of computing device 70A and interface devices 70B, as the previously unused peripheral regions of the wafer package 100 become available for device placement. As a result, the overall system density and functionality may be increased without necessarily expanding the footprint of the wafer package 100. Additionally, this configuration may lead to improved power delivery, enhanced signal integrity, and more efficient thermal management due to the strategic placement of voltage regulators 324 and external connectors 326 in close proximity to, respectively, the computing devices 70A and interface devices 70B.

An embodiment device includes a substrate package including a plurality of component substrates and a first encapsulant that is around and between the component substrates; a wafer package attached to a first side of the substrate package, the wafer package including a plurality of integrated circuit devices and a second encapsulant that is around and between the integrated circuit devices; a plurality of voltage regulators attached to a second side of the substrate package, the component substrates electrically connecting the voltage regulators to the integrated circuit devices; and a plurality of external connectors attached to the second side of the substrate package, the component substrates electrically connecting the external connectors to the integrated circuit devices. In some embodiments of the device, the substrate package further includes a first redistribution structure, the wafer package further includes a second redistribution structure, and the first redistribution structure is attached to the second redistribution structure. In some embodiments of the device, the component substrates are laid out in a grid within the substrate package in a top-down view. In some embodiments of the device, the component substrates include power distribution substrates and connector substrates, the voltage regulators attached to the power distribution substrates, the external connectors attached to the connector substrates. In some embodiments of the device, the voltage regulators are disposed inside a perimeter of the wafer package in a top-down view, and the external connectors are disposed outside the perimeter of the wafer package in the top-down view. In some embodiments of the device, the voltage regulators are disposed inside a perimeter of the wafer package in a top-down view, and the external connectors are disposed inside the perimeter of the wafer package in the top-down view. In some embodiments of the device, the external connectors are ribbon cable receptors. In some embodiments of the device, the wafer package is circle-shaped and the substrate package is square-shaped. In some embodiments of the device, it further includes a thermal module; a frame having openings exposing the external connectors, where the substrate package and the wafer package are disposed between the frame and the thermal module; and a plurality of bolts extending through the thermal module and the frame.

An embodiment device includes a thermal module; a frame including openings; and a system package between the thermal module and the frame, the system package including: a substrate package including a plurality of connector substrates, an encapsulant that is around and between the connector substrates, and a redistribution structure on the encapsulant; a wafer package attached to the redistribution structure of the substrate package, a width of the substrate package being greater than a width of the wafer package, the wafer package including integrated circuit devices; and a plurality of external connectors attached to the connector substrates of the substrate package, the connector substrates electrically connecting the external connectors to the integrated circuit devices, the openings of the frame exposing the external connectors. In some embodiments of the device, it further includes a plurality of bolts extending through the thermal module and the frame. In some embodiments of the device, an upper surface of the encapsulant is coplanar with upper surfaces of the connector substrates, and the redistribution structure is on the upper surface of the encapsulant and the upper surfaces of the connector substrates. In some embodiments of the device, at least one of the connector substrates include a substrate core and a passive device in the substrate core. In some embodiments of the device, at least one of the connector substrates is a coreless substrate.

An embodiment method includes forming a substrate package by: encapsulating a connector substrate and a power distribution substrate with a molding compound; planarizing the molding compound until an upper surface of the molding compound is coplanar with an upper surface of the connector substrate and an upper surface of the power distribution substrate; and forming a redistribution structure on the molding compound, the redistribution structure including redistribution lines that are electrically connected to the connector substrate and the power distribution substrate; attaching a wafer package to the redistribution structure of the substrate package; and attaching an external connector and a voltage regulator to, respectively, a lower surface of the connector substrate and a lower surface of the power distribution substrate. In some embodiments of the method, the substrate package is formed on a carrier substrate, and forming the substrate package further includes removing the carrier substrate to expose the lower surface of the connector substrate and the lower surface of the power distribution substrate. In some embodiments of the method, it further includes forming the power distribution substrate by: forming an opening in a substrate core; and placing a passive device in the opening. In some embodiments of the method, a width of the connector substrate is less than a width of the wafer package, a width of the power distribution substrate is less than the width of the wafer package, and a width of the substrate package is greater than the width of the wafer package. In some embodiments of the method, it further includes drilling bolt holes in the substrate package and the wafer package; and fastening the substrate package and the wafer package between a thermal module and a frame with bolts extending through the bolt holes. In some embodiments of the method, the voltage regulator is placed inside a perimeter of the wafer package in a top-down view, and the external connector is placed outside the perimeter of the wafer package in the top-down view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

WHAT IS CLAIMED IS:

1. A device comprising:
a substrate package comprising a plurality of component substrates and a first encapsulant that is around and between the component substrates;
a wafer package attached to a first side of the substrate package, the wafer package comprising a plurality of integrated circuit devices and a second encapsulant that is around and between the integrated circuit devices;
a plurality of voltage regulators attached to a second side of the substrate package, the component substrates electrically connecting the voltage regulators to the integrated circuit devices; and
a plurality of external connectors attached to the second side of the substrate package, the component substrates electrically connecting the external connectors to the integrated circuit devices.

2. The device of claim 1, wherein the substrate package further comprises a first redistribution structure, the wafer package further comprises a second redistribution structure, and the first redistribution structure is attached to the second redistribution structure.

3. The device of claim 1, wherein the component substrates are laid out in a grid within the substrate package in a top-down view.

4. The device of claim 1, wherein the component substrates comprise power distribution substrates and connector substrates, the voltage regulators attached to the power distribution substrates, the external connectors attached to the connector substrates.

5. The device of claim 1, wherein the voltage regulators are disposed inside a perimeter of the wafer package in a top-down view, and the external connectors are disposed outside the perimeter of the wafer package in the top-down view.

6. The device of claim 1, wherein the voltage regulators are disposed inside a perimeter of the wafer package in a top-down view, and the external connectors are disposed inside the perimeter of the wafer package in the top-down view.

7. The device of claim 1, wherein the external connectors are ribbon cable receptors.

8. The device of claim 1, wherein the wafer package is circle-shaped and the substrate package is square-shaped.

9. The device of claim 1, further comprising:
a thermal module;
a frame having openings exposing the external connectors, wherein the substrate package and the wafer package are disposed between the frame and the thermal module; and
a plurality of bolts extending through the thermal module and the frame.

10. A device comprising:
a thermal module;
a frame comprising openings; and
a system package between the thermal module and the frame, the system package comprising:
a substrate package comprising a plurality of connector substrates, an encapsulant that is around and between the connector substrates, and a redistribution structure on the encapsulant;
a wafer package attached to the redistribution structure of the substrate package, a width of the substrate package being greater than a width of the wafer package, the wafer package comprising integrated circuit devices; and
a plurality of external connectors attached to the connector substrates of the substrate package, the connector substrates electrically connecting the external connectors to the integrated circuit devices, the openings of the frame exposing the external connectors.

11. The device of claim 10, further comprising:
a plurality of bolts extending through the thermal module and the frame.

12. The device of claim 10, wherein an upper surface of the encapsulant is coplanar with upper surfaces of the connector substrates, and the redistribution structure is on the upper surface of the encapsulant and the upper surfaces of the connector substrates.

13. The device of claim 10, wherein at least one of the connector substrates comprise a substrate core and a passive device in the substrate core.

14. The device of claim 10, wherein at least one of the connector substrates is a coreless substrate.

15. A method comprising:
forming a substrate package by:
encapsulating a connector substrate and a power distribution substrate with a molding compound;
planarizing the molding compound until an upper surface of the molding compound is coplanar with an upper surface of the connector substrate and an upper surface of the power distribution substrate; and
forming a redistribution structure on the molding compound, the redistribution structure comprising redistribution lines that are electrically connected to the connector substrate and the power distribution substrate;
attaching a wafer package to the redistribution structure of the substrate package; and
attaching an external connector and a voltage regulator to, respectively, a lower surface of the connector substrate and a lower surface of the power distribution substrate.

16. The method of claim 15, wherein the substrate package is formed on a carrier substrate, and forming the substrate package further comprises:
removing the carrier substrate to expose the lower surface of the connector substrate and the lower surface of the power distribution substrate.

17. The method of claim 15, further comprising forming the power distribution substrate by:
forming an opening in a substrate core; and
placing a passive device in the opening.

18. The method of claim 15, wherein a width of the connector substrate is less than a width of the wafer package, a width of the power distribution substrate is less than the width of the wafer package, and a width of the substrate package is greater than the width of the wafer package.

19. The method of claim 15, further comprising:
drilling bolt holes in the substrate package and the wafer package; and
fastening the substrate package and the wafer package between a thermal module and a frame with bolts extending through the bolt holes.

20. The method of claim 15, wherein the voltage regulator is placed inside a perimeter of the wafer package in a top-down view, and the external connector is placed outside the perimeter of the wafer package in the top-down view.
